(19) United States
(12) Patent Application Publication
(10) Pub. No.: US 2025/0096133 A1
(43) Pub. Date: Mar. 20, 2025

(54) INTEGRATED CIRCUIT DEVICE

(71) Applicant: Samsung Electronics Co., Ltd., Suwon-si (KR)

(72) Inventors: Seowoo NAM, Suwon-si (KR); Heonjong SHIN, Suwon-si (KR); Juneyoung PARK, Suwon-si (KR); Sanghee LEE, Suwon-si (KR)

(73) Assignee: Samsung Electronics Co., Ltd., Suwon-si (KR)

(21) Appl. No.: 18/645,765

(22) Filed: Apr. 25, 2024

(30) Foreign Application Priority Data
Sep. 20, 2023 (KR) 10-2023-0125848

(51) Int. Cl. H01L 23/528; H01L 27/088; H01L 29/06; H01L 29/08; H01L 29/417; H01L 29/423; H01L 29/775; H01L 29/786

(52) U.S. Cl. CPC H01L 23/5283; H10D 30/43; H10D 30/6729; H10D 30/6735; H10D 30/6757; H10D 62/121; H10D 62/151; H10D 84/83

(57) ABSTRACT

An integrated circuit device includes a fin-type active region extending in a first horizontal direction on a substrate, a plurality of nanosheets facing a fin top of the fin-type active region, a gate line on the fin-type active region, the gate line surrounding each of the nanosheets and extending in a second horizontal direction, and a source/drain region on the fin-type active region. The gate line includes a main gate portion on the nanosheet stack, a first sub gate portion, a second sub gate portion, and a third sub gate portion. A width of the first sub gate portion in the first horizontal direction is greater than or equal to a width of the third sub gate portion in the first horizontal direction and the width of the first sub gate portion is less than a width of the second sub gate portion in the first horizontal direction.

### CROSS-REFERENCE TO RELATED APPLICATION

This application is based on and claims priority under 35 U.S.C. § 119 to Korean Patent Application No. 10-2023-0125848, filed on Sep. 20, 2023, in the Korean Intellectual Property Office, the disclosure of which is incorporated by reference herein in its entirety.

### BACKGROUND

The inventive concepts relate to an integrated circuit device, and more particularly, to an integrated circuit device including a nanosheet.

With the demand for compact and multi-functionalized high-performance electronic products, high capacity and high integration density of integrated circuit devices are required. Accordingly, it is necessary to efficiently design interconnection structures to ensure desired functions and operating speed of an integrated circuit device and achieve high integration density.

### SUMMARY

The present disclosure provides an integrated circuit device having increased performance and reliability.

Example embodiments provide an integrated circuit device that includes a fin-type active region extending in a first horizontal direction on a substrate; a nanosheet stack including a plurality of nanosheets facing a fin top of the fin-type active region, the nanosheet stack is separated from the fin top of the fin-type active region; a gate line on the fin-type active region, the gate line surrounding each of the plurality of nanosheets and the gate line extending in a second horizontal direction that crosses the first horizontal direction; a source/drain region on the fin-type active region, the source/drain region being adjacent to the gate line and the source/drain region being in contact with the plurality of nanosheets; and a backside contact penetrating the substrate and the backside contact electrically connected to the source/drain region. The gate line includes a main gate portion on a top surface of the nanosheet stack and the gate line includes a plurality of sub gate portions between the main gate portion and the fin-type active region. The plurality of sub gate portions include a first sub gate portion on the fin top of the fin-type active region, a second sub gate portion on the first sub gate portion, and a third sub gate portion on the second sub gate portion. A width of the first sub gate portion in the first horizontal direction is greater than or equal to a width of the third sub gate portion in the first horizontal direction and the width of the first sub gate portion is less than a width of the second sub gate portion in the first horizontal direction.

Example embodiments further provide an integrated circuit device that includes a fin-type active region extending in a first horizontal direction on a substrate; a channel region on the fin-type active region; a gate line on the fin-type active region, the gate line surrounding the channel region and the gate line extending in a second horizontal direction that crosses the first horizontal direction; and a source/drain region on the fin-type active region, the source/drain region being adjacent to the gate line and the source/drain region is in contact with the channel region. The gate line includes a main gate portion and a plurality of sub gate portions between the main gate portion and the fin-type active region. The main gate portion is at a higher vertical level than the channel region. The plurality of sub gate portions include a first sub gate portion on a fin top of the fin-type active region, a second sub gate portion on the first sub gate portion, and a third sub gate portion on the second sub gate portion. A width of the first sub gate portion in the first horizontal direction is less than a width of the second sub gate portion in the first horizontal direction. The first sub gate portion includes a first side surface and a second side surface overlapping the first side surface in the first horizontal direction. The first side surface of the first sub gate portion is indented toward the second side surface of the first sub gate portion.

Example embodiments still further provide an integrated circuit device that includes a fin-type active region extending in a first horizontal direction on a substrate; a nanosheet stack including a plurality of nanosheets facing a fin top of the fin-type active region, the nanosheet stack is separated from the fin top of the fin-type active region; a gate line on the fin-type active region, the gate line surrounding each of the plurality of nanosheets and the gate line extending in a second horizontal direction that crosses the first horizontal direction; and a source/drain region on the fin-type active region, the source/drain region being adjacent to the gate line and the source/drain region being in contact with the plurality of nanosheets. The gate line includes a main gate portion on a top surface of the nanosheet stack and the gate line includes a plurality of sub gate portions respectively below the plurality of nanosheets. The plurality of sub gate portions include a first sub gate portion, a second sub gate portion, a third sub gate portion, and a fourth sub gate portion that are sequentially arranged on the fin top of the fin-type active region. A width of the second sub gate portion in the first horizontal direction is greater than a width of the first sub gate portion in the first horizontal direction and the width of the second sub gate portion is less than a width of the third sub gate portion in the first horizontal direction. A width of the fourth sub gate portion in the first horizontal direction is less than the width of the third sub gate portion in the first horizontal direction. The plurality of nanosheets include a first nanosheet between the first sub gate portion and the second sub gate portion, a second nanosheet between the second sub gate portion and the third sub gate portion, a third nanosheet between the third sub gate portion and the fourth sub gate portion, and a fourth nanosheet between the fourth sub gate portion and the main gate portion. A width of the fourth nanosheet in the first horizontal direction is greater than a width of the third nanosheet in the first horizontal direction.

### BRIEF DESCRIPTION OF THE DRAWINGS

Some example embodiments will be more clearly understood from the following detailed description taken in conjunction with the accompanying drawings in which:

FIG. 1 is a plan layout diagram illustrating an integrated circuit device according to some example embodiments;

FIGS. 2A and 2B are cross-sectional views illustrating an integrated circuit device according to some example embodiments;

FIG. 3 is an enlarged cross-sectional view illustrating an integrated circuit device according to some example embodiments;

FIGS. 4 and 5 are enlarged cross-sectional views illustrating integrated circuit devices according to some example embodiments;

FIGS. 6A, 6B, 7, and 8 are cross-sectional views illustrating integrated circuit devices according to some example embodiments;

FIGS. 9A, 9B, 10, 11, and 12 are cross-sectional views illustrating integrated circuit devices according to some example embodiments; and

FIGS. 13A, 13B, 13C, 13D, 13E, 13F, 13G, 13H, 13I, 13J, 13K, 13L, 13M, 13N, 130, 13P, 13Q and 13R are cross-sectional views of sequential stages in a method of manufacturing an integrated circuit device, according to some example embodiments.

### DETAILED DESCRIPTION

Hereinafter, some example embodiments are described with reference to the accompanying drawings. In the drawings, like reference characters denote like elements, and redundant descriptions thereof will be omitted.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

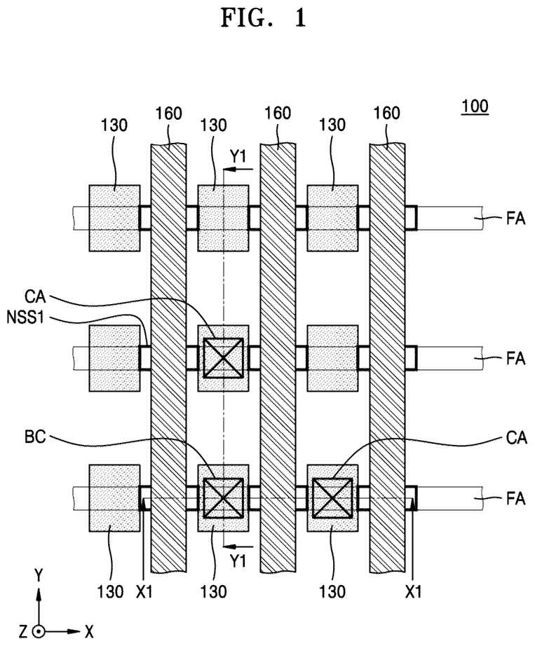

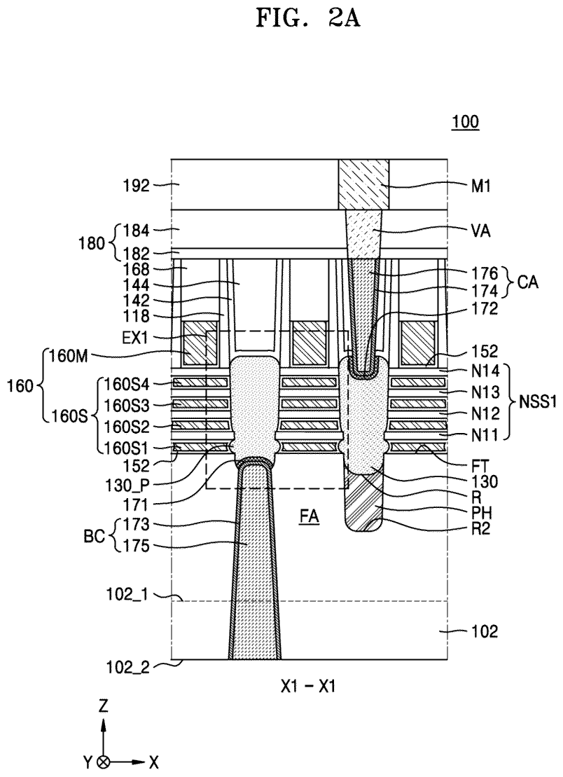

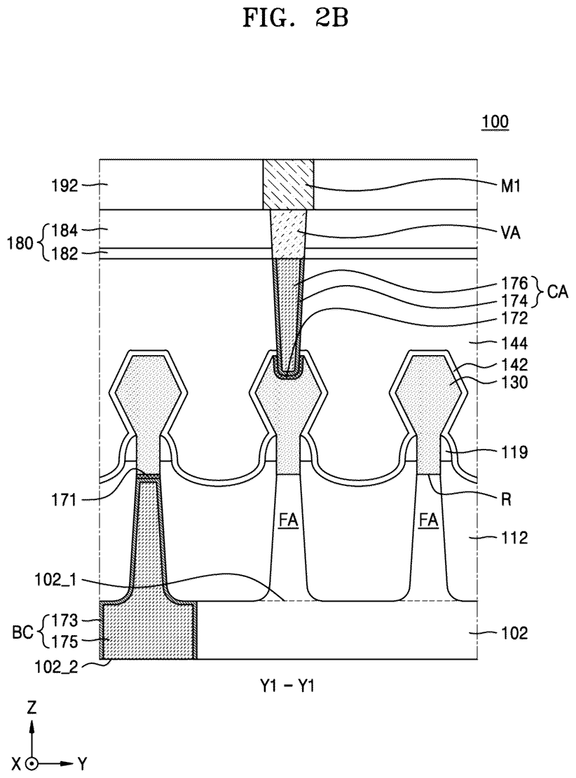

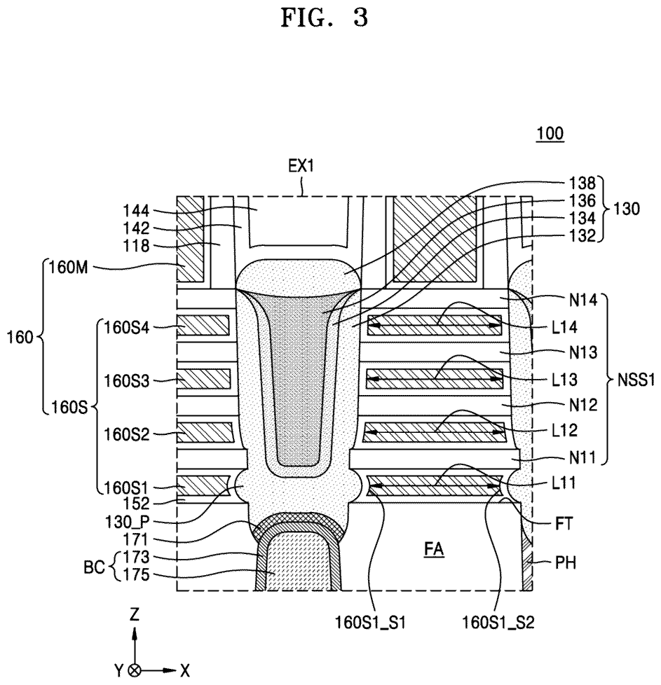

FIG. 1 is a plan layout diagram illustrating an integrated circuit device 100 according to some example embodiments. FIGS. 2A and 2B are cross-sectional views illustrating the integrated circuit device 100 according to some example embodiments. FIG. 3 is an enlarged cross-sectional view illustrating the integrated circuit device 100 according to some example embodiments. For example, FIG. 2A is a cross-sectional view taken along line X1-X1 in FIG. 1. FIG. 2B is a cross-sectional view taken along line Y1-Y1 in FIG. 1. FIG. 3 is an enlarged cross-sectional view of a region EX1 in FIG. 2A.

An integrated circuit device 100 including a field-effect transistor having a gate-all-around, which includes an active region having a nanowire or nanosheet shape and a gate surrounding the active region, is described below with reference to FIGS. 1 to 2B.

The integrated circuit device 100 may include a substrate 102, which has a first surface 102_1 and a second surface 102_2, and a plurality of fin-type active regions FA protruding from the first surface 102_1 of the substrate 102. The fin-type active regions FA may extend long in a first horizontal direction (the X direction) to be parallel with each other on the substrate 102.

The substrate 102 may include a semiconductor, such as Si or Ge, or a compound semiconductor, such as SiGe, SiC, GaAs, InAs, InGaAs, or InP. Each of the terms “SiGe”, “SiC”, “GaAs”, “InAs”, “InGaAs”, and “InP” used herein indicates a material composed of elements included in each term and is not a chemical equation representing stoichiometric relationships. The substrate 102 may include a conductive region, e.g., an impurity-doped well or an impurity-doped structure.

An isolation film 112 may be in a trench defining the fin-type active regions FA. The isolation film 112 may cover a portion of a sidewall of each of the fin-type active regions FA to be apart from the substrate 102 in the vertical direction (the Z direction). The isolation film 112 may include a silicon oxide film. The isolation film 112 may include a material having a different etch selectivity than a material of the substrate 102.

As shown in FIGS. 1 and 2A, a plurality of gate lines 160 may be on the fin-type active regions FA. Each of the gate lines 160 may extend long in a second horizontal direction (the Y direction) that crosses the first horizontal direction (the X direction). Each of a plurality of nanosheet stacks NSS1 may be above a fin top FT of a fin-type active region FA where the fin-type active region FA intersects with one of the gate lines 160. Each of the nanosheet stacks NSS1 may include at least one nanosheet, which faces the fin top FT of the fin-type active region FA at a position separated in the vertical direction (the Z direction) from the fin top FT of the fin-type active region FA. The term “nanosheet” used herein refers to a conductive structure having a cross-section that is substantially perpendicular to a direction in which electric current flows. For example, it should be understood that the nanosheet may include a nanowire.

As shown in FIG. 2A, each of the nanosheet stacks NSS1 may include a first nanosheet N11, a second nanosheet N12, a third nanosheet N13, and a fourth nanosheet N14, which overlap each other above the fin-type active region FA in the vertical direction (the Z direction). The first nanosheet N11, the second nanosheet N12, the third nanosheet N13, and the fourth nanosheet N14 may respectively have different vertical distances (Z-direction distances) from the fin top FT of the fin-type active region FA. Each of the gate lines 160 may surround the first nanosheet N11, the second nanosheet N12, the third nanosheet N13, and the fourth nanosheet N14 of a nanosheet stack NSS1, which overlap each other in the vertical direction (the Z direction).

Although the planar shape of the nanosheet stack NSS1 is substantially a rectangle in FIG. 1, some example embodiments are not limited thereto. The nanosheet stack NSS1 may have various planar shapes according to the planar shape of each of the fin-type active region FA and the gate lines 160. In some example embodiments as illustrated, a configuration is shown in which the plurality of nanosheet stacks NSS1 and the plurality of gate lines 160 are arranged on one fin-type active region FA and the nanosheet stacks NSS1 are arranged on the fin-type active region FA in line in the first horizontal direction (the X direction). The numbers of nanosheet stacks NSS1 and gate lines 160, which are arranged on one fin-type active region FA, are not limited.

Each of the first nanosheet N11, the second nanosheet N12, the third nanosheet N13, and the fourth nanosheet N14 of the nanosheet stack NSS1 may function as a channel region. In some example embodiments, each of the first nanosheet N11, the second nanosheet N12, the third nanosheet N13, and the fourth nanosheet N14 may have a thickness selected from a range from about 4 nm to about 6 nm but is not limited thereto. The thickness of each of the first nanosheet N11, the second nanosheet N12, the third nanosheet N13, and the fourth nanosheet N14 refers to a size in the vertical direction (the Z direction). In some example embodiments, the first nanosheet N11, the second nanosheet N12, the third nanosheet N13, and the fourth nanosheet N14 may have substantially the same thickness as one another in the vertical direction (the Z direction). In some example embodiments, at least some of the first nanosheet N11, the second nanosheet N12, the third nanosheet N13, and the fourth nanosheet N14 may have different thicknesses from each other in the vertical direction (the Z direction). In some example embodiments, each of the first nanosheet N11, the second nanosheet N12, the third nanosheet N13, and the fourth nanosheet N14 of the nanosheet stack NSS1 may include an Si layer, an SiGe layer, or a combination thereof.

As shown in FIG. 2A, at least some of the first nanosheet N11, the second nanosheet N12, the third nanosheet N13, and the fourth nanosheet N14 of one nanosheet stack NSS1 may have different sizes from each other in the first horizontal direction (the X direction).

For example, referring to FIG. 3, the first nanosheet N11 has the largest width in the first horizontal direction (the X direction), and the width in the first horizontal direction (the X direction) decreases in the order of the second nanosheet N12, the third nanosheet N13, and the fourth nanosheet N14.

For example, the width of the first nanosheet N11 in the first horizontal direction (the X direction) may be greater than the width of the second nanosheet N12 in the first horizontal direction (the X direction). The width of the second nanosheet N12 in the first horizontal direction (the X direction) may be greater than the width of the third nanosheet N13 in the first horizontal direction (the X direction). The width of the third nanosheet N13 in the first horizontal direction (the X direction) may be greater than the width of the fourth nanosheet N14 in the first horizontal direction (the X direction).

Although each of the nanosheet stacks NSS1 includes four nanosheets as illustrated in some example embodiments, the inventive concepts are not limited thereto. For example, a nanosheet stack NSS1 may include at least one nanosheet, and the number of nanosheets forming the nanosheet stack NSS1 is not limited.

As shown in FIG. 2A, each of the gate lines 160 may include a main gate portion 160M and a plurality of sub gate portions 160S. The main gate portion 160M may extend long in the second horizontal direction (the Y direction) to cover the top surface of the nanosheet stack NSS1. The sub gate portions 160S may be integrally connected to the main gate portion 160M and respectively between the fourth nanosheet N14 and the third nanosheet N13, between the third nanosheet N13 and the second nanosheet N12, between the second nanosheet N12 and the first nanosheet N11, and between the first nanosheet N11 and the fin-type active region FA. The sub gate portions 160S may include a first sub gate portion 160S1 between the first nanosheet N11 and the fin-type active region FA, a second sub gate portion 160S2 between the first nanosheet N11 and the second nanosheet N12, a third sub gate portion 160S3 between the second nanosheet N12 and the third nanosheet N13, and a fourth sub gate portion 160S4 between the third nanosheet N13 and the fourth nanosheet N14.

The thickness of each of the sub gate portions 160S in the vertical direction (the Z direction) may be less than the thickness of the main gate portion 160M in the vertical direction (the Z direction). In some example embodiments, the sub gate portions 160S may have different widths in the first horizontal direction (the X direction) from each other.

For example, the respective widths of the first sub gate portion 160S1, the second sub gate portion 160S2, the third sub gate portion 160S3, and the fourth sub gate portion 160S4 in the first horizontal direction (the X direction) may be different from one another.

In some example embodiments, the width of each of the second sub gate portion 160S2, the third sub gate portion 160S3, and the fourth sub gate portion 160S4 in the first horizontal direction (the X direction) may decrease as the vertical level thereof increases. For example, a width L14 of the fourth sub gate portion 160S4 located at the highest vertical level among the first to fourth sub gate portions 160S1 to 160S4 may be the smallest, and the third sub gate portion 160S3 may have a greater width in the first horizontal direction (the X direction) than the fourth sub gate portion 160S4 and the second sub gate portion 160S2 may have a greater width in the first horizontal direction (the X direction) than the third sub gate portion 160S3.

In some example embodiments, the width in the first horizontal direction (the X direction) of the first sub gate portion 160S1 located at the lowest vertical level among the first to fourth sub gate portions 160S1 to 160S4 may be less than the width of at least one of the sub gate portions 160S that are located at a higher vertical level than the first sub gate portion 160S1.

For example, a width L11 of the first sub gate portion 160S1 in the first horizontal direction (the X direction) may be less than any one of a width L12 of the second sub gate portion 160S2 in the first horizontal direction (the X direction) and a width L13 of the third sub gate portion 160S3 in the first horizontal direction (the X direction).

In some example embodiments, the width L11 of the first sub gate portion 160S1 in the first horizontal direction (the X direction) may be greater than or equal to the width L14 of the fourth sub gate portion 160S4 in the first horizontal direction (the X direction).

The first sub gate portion 160S1 may include two side surfaces, e.g., a first side surface 160S1_S1 and a second side surface 160S1_S2, which overlap each other in the first horizontal direction (the X direction). In some example embodiments, at least one of the first side surface 160S1_S1 and the second side surface 160S1_S2 may be indented toward the other one. For example, the first side surface 160S1_S1 may be indented toward the second side surface 160S1_S2. For example, the second side surface 160S1_S2 may be indented toward the first side surface 160S1_S1.

In some example embodiments, the width of the first sub gate portion 160S1 in the first horizontal direction (the X direction) may not be uniform in the vertical direction (the Z direction). For example, the width of the first sub gate portion 160S1 in the first horizontal direction (the X direction) may decrease and then increase as the vertical level increases.

In some example embodiments, the width L11 of the first sub gate portion 160S1 in the first horizontal direction (the X direction) may refer to the average width of the first sub gate portion 160S1 in the first horizontal direction (the X direction). In some example embodiments, the width L11 of the first sub gate portion 160S1 in the first horizontal direction (the X direction) may refer to the minimum width of the first sub gate portion 160S1 in the first horizontal direction (the X direction). In some example embodiments, the width L11 of the first sub gate portion 160S1 in the first horizontal direction (the X direction) may refer to a width of the first sub gate portion 160S1 in the first horizontal direction (the X direction) at the intermediate vertical level of the first sub gate portion 160S1. The description of the width of the first sub gate portion 160S1 may also be applied to the second to fourth sub gate portions 160S2 to 160S4.

Each of the gate lines 160 may include metal, metal nitride, metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may include TiAlC. However, the material of the gate lines 160 is not limited to those described above.

As shown in FIG. 2A, a plurality of recesses R may be formed in the fin-type active region FA. The vertical level of the bottommost surface of each of the recesses R may be lower than the vertical level of the fin top FT of the fin-type active region FA.

As shown in FIG. 2A, a plurality of source/drain regions 130 may be respectively arranged in the recesses R. Each of the source/drain regions 130 may be adjacent to at least one of the gate lines 160. Each of the source/drain regions 130 may have surfaces respectively facing the first nanosheet N11, the second nanosheet N12, and the third nanosheet N13, which are included in a nanosheet stack NSS1 adjacent to each source/drain region 130. Each of the source/drain regions 130 may be in contact with the first nanosheet N11, the second nanosheet N12, and the third nanosheet N13, which are included in a nanosheet stack NSS1 adjacent to each source/drain region 130.

Each of the source/drain regions 130 may include a protrusion 130_P, which overlaps the first sub gate portion 160S1 in the first horizontal direction (the X direction). In some example embodiments, each of the source/drain regions 130 may not include a protrusion in a region that overlaps the other sub gate portions, e.g., the second to fourth sub gate portions 160S2, 160S3, and 160S4.

For example, referring to FIG. 3, a source/drain region 130 may include a plurality of semiconductor layers, which may include a first semiconductor layer 132, a second semiconductor layer 134, and a third semiconductor layer 136 that are sequentially arranged in the source/drain region 130. In some example embodiments, the semiconductor layers may further include a capping layer 138 on the third semiconductor layer 136.

The first semiconductor layer 132 may include a portion in contact with a channel region and a portion in contact with the fin-type active region FA. For example, the first semiconductor layer 132 may include a portion, which is in contact with the first nanosheet N11, the second nanosheet N12, the third nanosheet N13, and the fourth nanosheet N14, and a portion, which is in contact with the fin-type active region FA. The first semiconductor layer 132 may include a portion adjacent to the sub gate portions 160S.

In some example embodiments, the protrusion 130_P of the source/drain region 130 may be a portion of the first semiconductor layer 132. For example, the first semiconductor layer 132 may include a portion, which protrudes toward the first sub gate portion 160S1. The protrusion 130_P of the source/drain region 130 may protrude toward the first sub gate portion 160S1 in the first horizontal direction (the X direction). The protrusion 130_P of the source/drain region 130 may include an outer portion of the source/drain region 130, which protrudes toward the first sub gate portion 160S1 in the first horizontal direction (the X direction).

As described above, the protrusion 130_P of the source/drain region 130 may overlap the first sub gate portion 160S1 in the first horizontal direction (the X direction). In some example embodiments, as the source/drain region 130 includes the protrusion 130_P protruding toward the first sub gate portion 160S1, the first sub gate portion 160S1 may have a side surface indented inwards.

In some example embodiments, the protrusion 130_P of the source/drain region 130 may overlap the second sub gate portion 160S2 in the vertical direction (the Z direction). In some example embodiments, the protrusion 130_P of the source/drain region 130 may not overlap the second sub gate portion 160S2 in the vertical direction (the Z direction).

In some example embodiments, the width of the source/drain region 130 in the first horizontal direction (the X direction) may be minimum in a portion thereof that overlaps the first nanosheet N11. For example, the width of the source/drain region 130 in the first horizontal direction (the X direction), which is measured at a vertical level passing through the first nanosheet N11, may be minimum.

In some example embodiments, each of the first semiconductor layer 132, the second semiconductor layer 134, and the third semiconductor layer 136 of the source/drain region 130 may include an Si₁₋ₓGeₓ layer doped with a p-type dopant, where x=0. For example, the p-type dopant included in the source/drain region 130 may include, but is not limited to, boron (B), gallium (Ga), carbon (C), or a combination thereof.

In some example embodiments, each of the first semiconductor layer 132, the second semiconductor layer 134, and the third semiconductor layer 136 of the source/drain region 130 may include an Si layer doped with an n-type dopant.

As shown in FIG. 2A, a second recess R2 may be below each of some of the recesses R. The vertical level of the bottommost surface of the second recess R2 may be lower than the vertical level of the bottommost surface of the recess R.

A place holder PH may be in the second recess R2. The place holder PH may fill the second recess R2. The place holder PH may be below some source/drain regions 130. The place holder PH may be in contact with some source/drain regions 130.

In some example embodiments, the place holder PH may include SiGe. In some example embodiments, when a source/drain region 130 includes SiGe, a Ge concentration in the place holder PH may be different from a Ge concentration in the source/drain region 130.

A gate dielectric film 152 may be between a nanosheet stack NSS1 and a gate line 160. In some example embodiments, the gate dielectric film 152 may include a stack structure of an interface dielectric film and a high-k dielectric film. The interface dielectric film may include a low-k dielectric film, e.g., a silicon oxide film, a silicon oxynitride film, or a combination thereof, having a permittivity of about 9 or less. In some example embodiments, the interface dielectric film may be omitted. The high-k dielectric film may include a material having a higher dielectric constant than a silicon oxide film. For example, the high-k dielectric film may have a dielectric constant of about 10 to about 25. The high-k dielectric film may include hafnium oxide but is not limited thereto.

Each of the opposite sidewalls of each of the sub gate portions 160S of each of the gate lines 160 may be separated from the source/drain region 130 by the gate dielectric film 152. The gate dielectric film 152 may be between each of the sub gate portions 160S of each gate line 160 and one of the first nanosheet N11, the second nanosheet N12, the third nanosheet N13, and the fourth nanosheet N14 and between the sub gate portions 160S of the gate line 160 and the source/drain region 130.

In some example embodiments, according to a cross-sectional view taken along a line that is perpendicular to the second horizontal direction (the Y direction), the protrusion 130_P of the source/drain region 130 may overlap the gate dielectric film 152, which surrounds at least one selected from the group consisting of the second sub gate portion 160S2, the third sub gate portion 160S3, and the fourth sub gate portion 160S4, in the vertical direction (the Z direction). In some example embodiments, according to a cross-sectional view taken along a line that is perpendicular to the second horizontal direction (the Y direction), the protrusion 130_P of the source/drain region 130 may overlap at least one selected from the group consisting of the second sub gate portion 160S2, the third sub gate portion 160S3, and the fourth sub gate portion 160S4 in the vertical direction (the Z direction).

As shown in FIG. 2A, the top surface of each of the gate dielectric film 152 and the gate line 160 may be covered with a capping insulating pattern 168. The capping insulating pattern 168 may include a silicon nitride film.

Opposite sidewalls of each of the gate line 160 and the capping insulating pattern 168 may be respectively covered with outer insulating spacers 118. The outer insulating spacers 118 may be above the top surface of the nanosheet stacks NSS1 to respectively cover the opposite side walls of the main gate portion 160M. The outer insulating spacers 118 may be separated from the gate line 160 by the gate dielectric film 152.

As shown in FIG. 2B, a plurality of recess insulating spacers 119 may be on the top surface of the isolation film 112 to respectively cover the sidewalls of the source/drain region 130. In some example embodiments, each of the recess insulating spacers 119 may be integrally connected to the outer insulating spacer 118 adjacent to each recess insulating spacer 119.

The outer insulating spacers 118 and the recess insulating spacers 119 may include silicon nitride, silicon oxide, SiCN, SiBN, SION, SiOCN, SiBCN, SiOC, or a combination thereof. Each of the terms “SiCN”, “SiBN”, “SiON”, “SiOCN”, “SiBCN”, and “SiOC” used herein indicates a material composed of elements included in each term and is not a chemical equation representing stoichiometric relationships.

A first metal silicide film 172 may be on the top surface of some source/drain regions 130. The first metal silicide film 172 may include metal including Ti, W, Ru, Nb, Mo, Hf, Ni, Co, Pt, Yb, Tb, Dy, Er, or Pd. For example, the first metal silicide film 172 may include titanium silicide but is not limited thereto.

A plurality of source/drain regions 130, a plurality of first metal silicide films 172, and a plurality of outer insulating spacers 118 on the substrate 102 may be covered with an insulating liner 142. In some example embodiments, the insulating liner 142 may be omitted. An intergate insulating film 144 may be on the insulating liner 142. When the insulating liner 142 is omitted, the intergate insulating film 144 may be in contact with the source/drain regions 130.

The insulating liner 142 and the intergate insulating film 144 may be sequentially arranged on the source/drain regions 130 and the first metal silicide films 172. The insulating liner 142 and the intergate insulating film 144 may form an insulating structure. In some example embodiments, the insulating liner 142 may include, but is not limited to, silicon nitride, SiCN, SiBN, SiON, SiOCN, SiBCN, or a combination thereof. The intergate insulating film 144 may include a silicon oxide film but is not limited thereto.

Each of the nanosheet stacks NSS1 may be above the fin top FT of the fin-type active region FA where the fin-type active region FA intersects with one of the gate lines 160 and may face the fin top FT of the fin-type active region FA at a position separated from the fin-type active region FA. A plurality of nanosheet transistors may be formed above the substrate 102 where fin-type active regions FA intersect with the gate lines 160.

As shown in FIGS. 2A and 2B, an active contact CA may be on a source/drain region 130. The active contact CA may pass through the intergate insulating film 144 and the insulating liner 142 in the vertical direction (the Z direction) and be in contact with the first metal silicide film 172. The active contact CA may be configured to be electrically connected to the source/drain region 130 through the first metal silicide film 172.

The active contact CA may include a conductive barrier pattern 174 and a contact plug 176, which are sequentially stacked on the source/drain region 130. The conductive barrier pattern 174 may surround and be in contact with the bottom surface and sidewall of the contact plug 176. The active contact CA may extend long in the vertical direction (the Z direction) through the intergate insulating film 144 and the insulating liner 142. The conductive barrier pattern 174 may be between the first metal silicide film 172 and the contact plug 176. The conductive barrier pattern 174 may have a surface in contact with the first metal silicide film 172 and a surface in contact with the contact plug 176. In some example embodiments, the conductive barrier pattern 174 may include metal or metal nitride. For example, the conductive barrier pattern 174 may include, but is not limited to, Ti, Ta, W, TiN, TaN, WN, WCN, TiSiN, TaSiN, WSiN, or a combination thereof. The contact plug 176 may include, but is not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof.

As shown in FIGS. 2A and 2B, the top surfaces of the active contact CA, the capping insulating pattern 168, and the intergate insulating film 144 may be covered with an upper insulating structure 180. The upper insulating structure 180 may include an etch stop film 182 and an interlayer insulating film 184, which are sequentially stacked on the active contact CA, the capping insulating pattern 168, and the intergate insulating film 144. The etch stop film 182 may include silicon carbide (SiC), silicon nitride (SiN), nitrogen-doped silicon carbide (SiC: N), SiOC, AlN, AlON, AlO, AlOC, or a combination thereof. The interlayer insulating film 184 may include an oxide film, a nitride film, an ultra low-k (ULK) film having an ultra low dielectric constant K of about 2.2 to about 2.4, or a combination thereof. For example, the interlayer insulating film 184 may include, but is not limited to, a tetraethylorthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, or a combination thereof.

As shown in FIGS. 2A and 2B, a via contact VA may be on the active contact CA. The via contact VA may pass through the upper insulating structure 180 and be in contact with the active contact CA. The source/drain region 130 may be configured to be electrically connected to the via contact VA through the first metal silicide film 172 and the active contact CA. The bottom surface of the via contact VA may be in contact with the top surface of the active contact CA. The via contact VA may include, but is not limited to, W, Mo, and/or Ru.

As shown in FIGS. 2A and 2B, an interconnection line M1 may pass through an upper insulating film 192. The interconnection line M1 may be connected to the via contact VA therebelow. In some example embodiments, the interconnection line M1 may extend in the first horizontal direction (the X direction). The interconnection line M1 may include, but is not limited to, Mo, Cu, W, Co, Ru, Mn, Ti, Ta, Al, a combination thereof, or an alloy thereof.

As shown in FIGS. 2A and 2B, a backside contact BC may pass through the substrate 102 and be in contact with a source/drain region 130. The backside contact BC may pass through the substrate 102 and the fin-type active region FA in the vertical direction (the Z direction) and be in contact with a second metal silicide film 171. The backside contact BC may be configured to be electrically connectable to the source/drain region 130 through the second metal silicide film 171.

The backside contact BC may include a barrier pattern 173 and a conductive plug 175, which are sequentially stacked. The barrier pattern 173 may surround and be in contact with the sidewall and top surface of the conductive plug 175. The barrier pattern 173 may be between the second metal silicide film 171 and the conductive plug 175. The barrier pattern 173 may have a surface in contact with the second metal silicide film 171 and a surface in contact with the conductive plug 175.

In some example embodiments, the barrier pattern 173 may include metal or metal nitride. For example, the barrier pattern 173 may include, but is not limited to, Ti, Ta, W, TiN, TaN, WN, WCN, TiSiN, TaSiN, WSiN, or a combination thereof. The contact plug 175 may include, but is not limited to, Mo, Cu, W, Co, Ru, Mn, Ti, Ta, Al, a combination thereof, or an alloy thereof.

In some example embodiments, an insulating film may be arranged between the backside contact BC and the fin-type active region FA and between the backside contact BC and the substrate 102. The insulating film may include at least one selected from the group consisting of silicon oxide (SiO₂), silicon nitride (SiN), silicon carbonitride (SiCN), silicon oxynitride (SiON), silicon oxycarbide (SiOC), and silicon oxycarbonitride (SiOCN). The insulating film may be formed as a single film or may include multiple films including different materials from each other.

In the integrated circuit device 100 according to the some example embodiments described above with reference to FIGS. 1 to 3, the first sub gate portion 160S1, which overlaps the protrusion 130_P of a source/drain region 130 in the first horizontal direction (the X direction), may have a width in the first horizontal direction (the X direction) that is less than a width in the first horizontal direction (the X direction) of at least one of a plurality of sub gate portions 160S located at a higher vertical level than the first sub gate portion 160S1. For example, the integrated circuit device 100 may include the first sub gate portion 160S1 having a reduced width at the lowest vertical level among the sub gate portions 160S. As the width of the first sub gate portion 160S1 at the lowest vertical level is reduced, the distance between the first sub gate portion 160S1 and the backside contact BC may increase. Accordingly, the risk of the backside contact BC interfering with the first sub gate portion 160S1 may be reduced. Also, a margin by which the backside contact BC does not interfere with the first sub gate portion 160S1 may be improved. For example, according to some example embodiments of the inventive concepts, an integrated circuit device having increased performance and reliability may be provided.

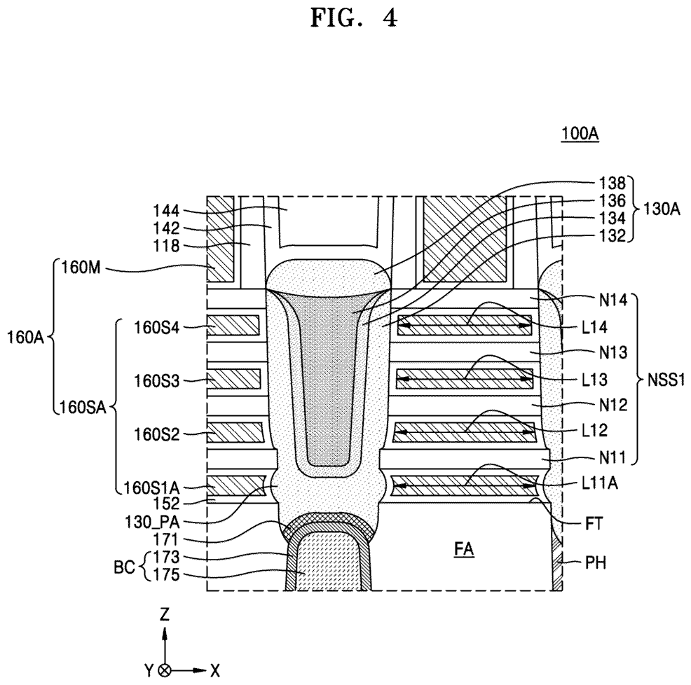

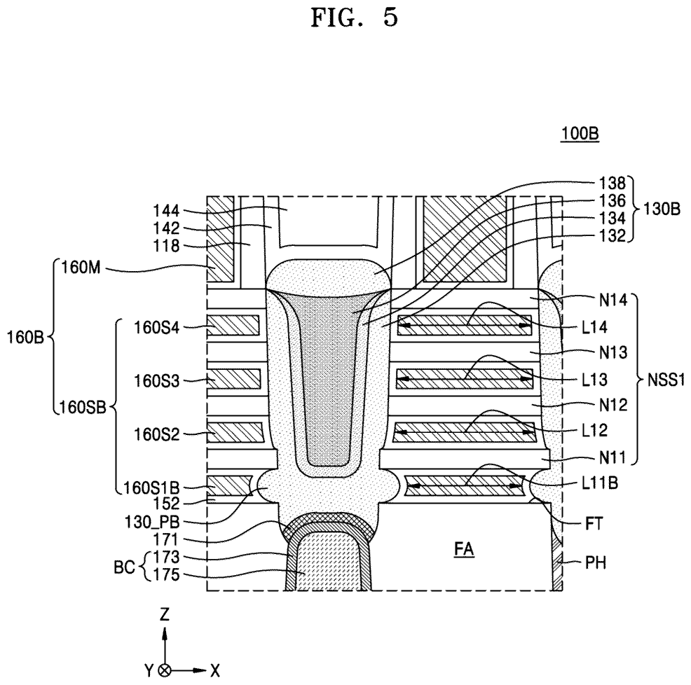

FIGS. 4 and 5 are enlarged cross-sectional views respectively illustrating integrated circuit devices 100A and 100B according to some example embodiments. For example, FIGS. 4 and 5 are enlarged cross-sectional views of regions which correspond to the region EX1 in FIG. 2A in the integrated circuit devices 100A and 100B, respectively. The integrated circuit devices 100A and 100B are described below, focusing on the differences from the integrated circuit device 100 described above with reference to FIGS. 1 to 3.

Referring to FIG. 4, the integrated circuit device 100A may be provided. The integrated circuit device 100A may include a gate line 160A, which extends long above a plurality of fin-type active regions FA in the second horizontal direction (the Y direction). The gate line 160A may include the main gate portion 160M and a plurality of sub gate portions 160SA. The sub gate portions 160SA may include a first sub gate portion 160S1A between the first nanosheet N11 and a fin-type active region FA, the second sub gate portion 160S2 between the first nanosheet N11 and the second nanosheet N12, the third sub gate portion 160S3 between the second nanosheet N12 and the third nanosheet N13, and the fourth sub gate portion 160S4 between the third nanosheet N13 and the fourth nanosheet N14.

In some example embodiments, the width L14 of the fourth sub gate portion 160S4 located at the highest vertical level among the first to fourth sub gate portions 160S1A to 160S4 may be the smallest, and the third sub gate portion 160S3 may have a greater width in the first horizontal direction (the X direction) than the fourth sub gate portion 160S4 and the second sub gate portion 160S2 may have a greater width in the first horizontal direction (the X direction) than the third sub gate portion 160S3.

In some example embodiments, a width L11A of the first sub gate portion 160S1A in the first horizontal direction (the X direction) may be less than the width L12 of the second sub gate portion 160S2 in the first horizontal direction (the X direction).

In some example embodiments, the width L11A of the first sub gate portion 160S1A in the first horizontal direction (the X direction) may be greater than or equal to the width L13 of the third sub gate portion 160S3 in the first horizontal direction (the X direction).

As shown in FIG. 4, a source/drain region 130A of the integrated circuit device 100A may include a protrusion 130_PA, which overlaps the first sub gate portion 160S1A in the first horizontal direction (the X direction).

Referring to FIG. 5, the integrated circuit device 100B may be provided. The integrated circuit device 100B may include a gate line 160B, which extends long above a plurality of fin-type active regions FA in the second horizontal direction (the Y direction). The gate line 160B may include the main gate portion 160M and a plurality of sub gate portions 160SB. The sub gate portions 160SB may include a first sub gate portion 160S1B between the first nanosheet N11 and a fin-type active region FA, the second sub gate portion 160S2 between the first nanosheet N11 and the second nanosheet N12, the third sub gate portion 160S3 between the second nanosheet N12 and the third nanosheet N13, and the fourth sub gate portion 160S4 between the third nanosheet N13 and the fourth nanosheet N14.

In some example embodiments, the width L14 of the fourth sub gate portion 160S4 located at the highest vertical level among the first to fourth sub gate portions 160S1B to 160S4 may be the smallest, and the third sub gate portion 160S3 may have a greater width in the first horizontal direction (the X direction) than the fourth sub gate portion 160S4 and the second sub gate portion 160S2 may have a greater width in the first horizontal direction (the X direction) than the third sub gate portion 160S3.

In some example embodiments, a width L11B of the first sub gate portion 160S1B in the first horizontal direction (the X direction) may be less than any one of the width L12 of the second sub gate portion 160S2 in the first horizontal direction (the X direction), the width L13 of the third sub gate portion 160S3 in the first horizontal direction (the X direction), and the width L14 of the fourth sub gate portion 160S4 in the first horizontal direction (the X direction).

As shown in FIG. 5, a source/drain region 130B of the integrated circuit device 100B may include a protrusion 130_PB, which overlaps the first sub gate portion 160S1B in the first horizontal direction (the X direction).

In some example embodiments, the width of the source/drain region 130B in the first horizontal direction (the X direction) may be maximum at the protrusion 130_PB thereof. For example, the width of the source/drain region 130B in the first horizontal direction (the X direction), which is measured at a vertical level passing through the protrusion 130_PB, may be maximum. For example, the width of the source/drain region 130B in the first horizontal direction (the X direction), which is measured at a vertical level passing through the first sub gate portion 160SB, may be maximum.

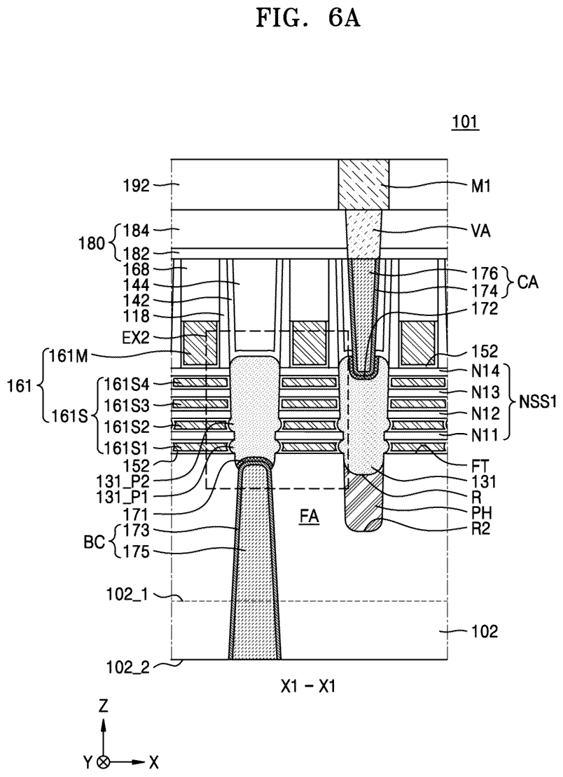

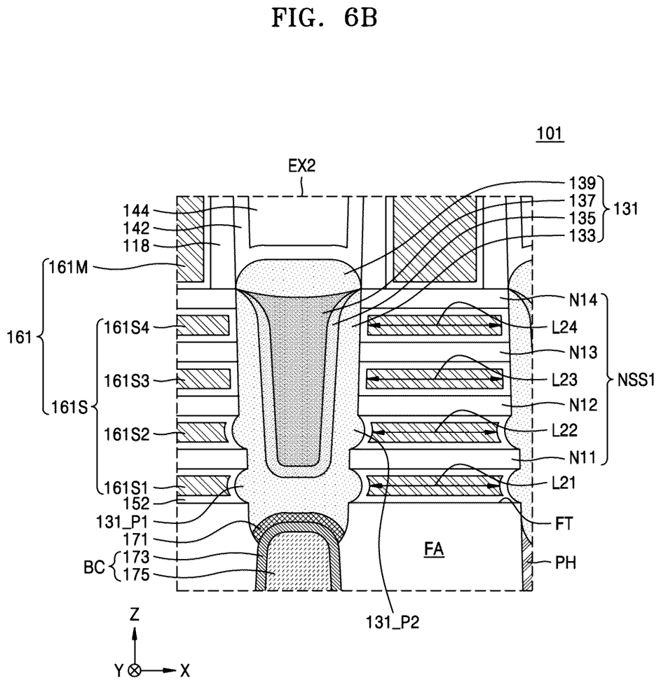

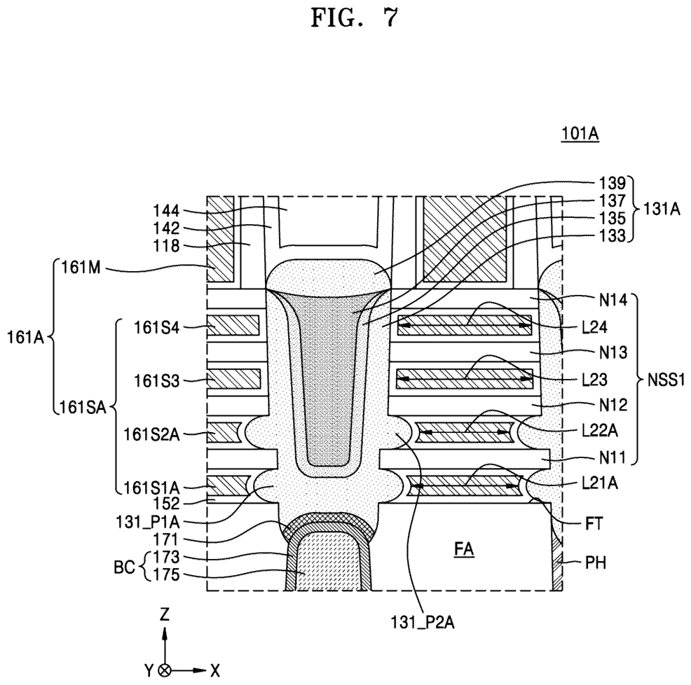

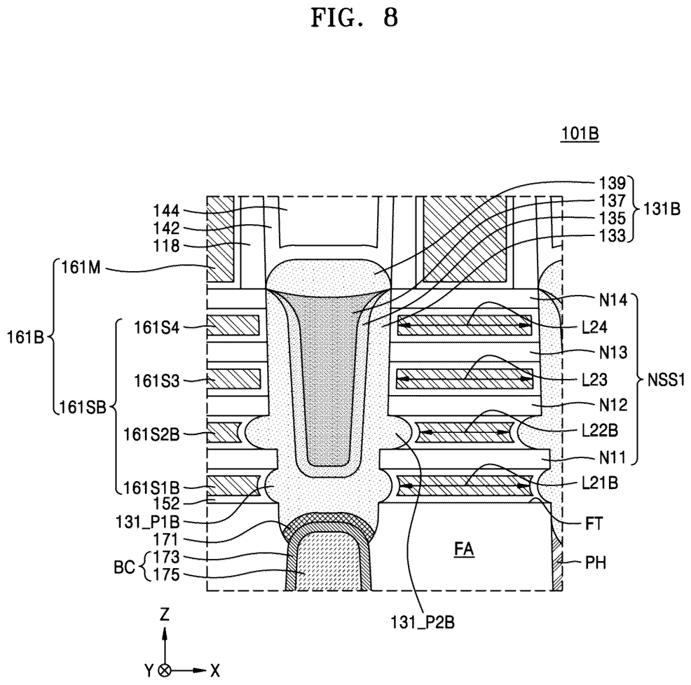

FIGS. 6A and 6B are cross-sectional views illustrating an integrated circuit device 101 according to some example embodiments. For example, FIG. 6B is an enlarged cross-sectional view of a region EX2 in FIG. 6A. FIGS. 7 and 8 are enlarged cross-sectional views of regions, which correspond to the region EX2 in FIG. 6A in integrated circuit devices 101A and 101B, respectively, according to some example embodiments.

The integrated circuit device 101 is described below with reference to FIGS. 6A and 6B, focusing on the differences from the integrated circuit device 100 described above with reference to FIGS. 1 to 3.

Referring to FIGS. 6A and 6B, the integrated circuit device 101 may be provided. The integrated circuit device 101 may include a gate line 161, which extends long above a plurality of fin-type active regions FA in the second horizontal direction (the Y direction). The gate line 161 may include a main gate portion 161M and a plurality of sub gate portions 161S. The sub gate portions 161S may include a first sub gate portion 161S1 between the first nanosheet N11 and a fin-type active region FA, a second sub gate portion 161S2 between the first nanosheet N11 and the second nanosheet N12, a third sub gate portion 161S3 between the second nanosheet N12 and the third nanosheet N13, and a fourth sub gate portion 161S4 between the third nanosheet N13 and the fourth nanosheet N14.

In some example embodiments, comparing the widths of the fourth sub gate portion 161S4 and the third sub gate portion 161S3 in the first horizontal direction (the X direction), a width L24 in the first horizontal direction (the X direction) of the fourth sub gate portion 161S4, which is located at a higher vertical level than the third sub gate portion 161S3, may be less than a width L23 of the third sub gate portion 161S3 in the first horizontal direction (the X direction).

In some example embodiments, comparing the widths of the second sub gate portion 161S2 and the first sub gate portion 161S1 in the first horizontal direction (the X direction), a width L22 in the first horizontal direction (the X direction) of the second sub gate portion 161S2, which is located at a higher vertical level than the first sub gate portion 161S1, may be less than a width L21 of the first sub gate portion 161S1 in the first horizontal direction (the X direction).

In some example embodiments, each of the width L21 of the first sub gate portion 161S1 and the width L22 of the second sub gate portion 161S2 in the first horizontal direction (the X direction) may be less than the width L23 of the third sub gate portion 161S3 in the first horizontal direction (the X direction).

In some example embodiments, the width L21 of the first sub gate portion 161S1 in the first horizontal direction (the X direction) may be greater than or equal to the width L24 of the fourth sub gate portion 161S4 in the first horizontal direction (the X direction).

As shown in FIGS. 6A and 6B, the integrated circuit device 101 may include a plurality of source/drain regions 131. Each of the source/drain regions 131 may include a plurality of semiconductor layers. The semiconductor layers may include a first semiconductor layer 133, a second semiconductor layer 135, and a third semiconductor layer 137 that are sequentially arranged in each source/drain region 131. In some example embodiments, the semiconductor layers may further include a capping layer 139 on the third semiconductor layer 137.

In some example embodiments, each of the source/drain regions 131 may include a first protrusion 131_P1, which overlaps the first sub gate portion 161S1 in the first horizontal direction (the X direction), and a second protrusion 131_P2, which overlaps the second sub gate portion 161S2 in the first horizontal direction (the X direction). In some example embodiments, each of the source/drain regions 131 may not include a protrusion in a region that overlaps the other sub gate portions, e.g., the third and fourth sub gate portions 161S3 and 161S4.

In some example embodiments, the width of each of the source/drain regions 131 in the first horizontal direction (the X direction) may be minimum in a portion thereof that overlaps the first nanosheet N11. For example, the width of the source/drain region 131 in the first horizontal direction (the X direction), which is measured at a vertical level passing through the first nanosheet N11, may be minimum. In some example embodiments, the width of the source/drain region 131 in the first horizontal direction (the X direction) may be minimum between the first protrusion 131_P1 and the second protrusion 131_P2 of the source/drain region 131.

In some example embodiments, the second protrusion 131_P2 of the source/drain region 131 may protrude further toward the sub gate portions 161S than the first protrusion 131_P1 of the source/drain region 131. In some example embodiments, the first protrusion 131_P1 of the source/drain region 131 may protrude further toward the sub gate portions 161S than the second protrusion 131_P2 of the source/drain region 131. In some example embodiments, the first protrusion 131_P1 of the source/drain region 131 may protrude toward the sub gate portions 161S by the same length as the second protrusion 131_P2 of the source/drain region 131.

Referring to FIG. 7, the integrated circuit device 101A may be provided. The integrated circuit device 101A is described below, focusing on the differences from the integrated circuit device 101 described above with reference to FIGS. 6A and 6B.

The integrated circuit device 101A may include a gate line 161A, which extends long above a plurality of fin-type active regions FA in the second horizontal direction (the Y direction). The gate line 161A may include the main gate portion 161M and a plurality of sub gate portions 161SA. The sub gate portions 161SA may include a first sub gate portion 161S1A between the first nanosheet N11 and a fin-type active region FA, a second sub gate portion 161S2A between the first nanosheet N11 and the second nanosheet N12, the third sub gate portion 161S3 between the second nanosheet N12 and the third nanosheet N13, and the fourth sub gate portion 161S4 between the third nanosheet N13 and the fourth nanosheet N14.

In some example embodiments, the width L24 of the fourth sub gate portion 161S4 in the first horizontal direction (the X direction) may be less than the width L23 of the third sub gate portion 161S3 in the first horizontal direction (the X direction). A width L22A of the second sub gate portion 161S2A in the first horizontal direction (the X direction) may be less than a width L21A of the first sub gate portion 161S1A in the first horizontal direction (the X direction).

In some example embodiments, each of the width L21A of the first sub gate portion 161S1A and the width L22A of the second sub gate portion 161S2A in the first horizontal direction (the X direction) may be less than the width L24 of the fourth sub gate portion 161S4 in the first horizontal direction (the X direction).

As shown in FIG. 7, a source/drain region 131A of the integrated circuit device 101A may include a first protrusion 131_P1A, which overlaps the first sub gate portion 161S1A in the first horizontal direction (the X direction), and a second protrusion 131_P2A, which overlaps the second sub gate portion 161S2A in the first horizontal direction (the X direction).

In some example embodiments, the width of the source/drain region 131A in the first horizontal direction (the X direction) may be maximum at the second protrusion 131_P2A thereof. For example, the width of the source/drain region 131A in the first horizontal direction (the X direction), which is measured at a vertical level passing through the second protrusion 131_P2A, may be maximum. For example, the width of the source/drain region 131A in the first horizontal direction (the X direction), which is measured at a vertical level passing through the second sub gate portion 161S2A, may be maximum.

Referring to FIG. 8, the integrated circuit device 101B may be provided. The integrated circuit device 101B is described below, focusing on the differences from the integrated circuit device 101 described above with reference to FIGS. 6A and 6B.

The integrated circuit device 101B may include a gate line 161B, which extends long above a plurality of fin-type active regions FA in the second horizontal direction (the Y direction). The gate line 161B may include the main gate portion 161M and a plurality of sub gate portions 161SB. The sub gate portions 161SB may include a first sub gate portion 161S1B between the first nanosheet N11 and a fin-type active region FA, a second sub gate portion 161S2B between the first nanosheet N11 and the second nanosheet N12, the third sub gate portion 161S3 between the second nanosheet N12 and the third nanosheet N13, and the fourth sub gate portion 161S4 between the third nanosheet N13 and the fourth nanosheet N14.

In some example embodiments, the width L24 of the fourth sub gate portion 161S4 in the first horizontal direction (the X direction) may be less than the width L23 of the third sub gate portion 161S3 in the first horizontal direction (the X direction). A width L22B of the second sub gate portion 161S2B in the first horizontal direction (the X direction) may be less than a width L21B of the first sub gate portion 161S1B in the first horizontal direction (the X direction).

In some example embodiments, the width L21B of the first sub gate portion 161S1B in the first horizontal direction (the X direction) may be greater than or equal to the width L24 of the fourth sub gate portion 161S4 in the first horizontal direction (the X direction). The width L22B of the second sub gate portion 161S2B in the first horizontal direction (the X direction) may be less than the width L24 of the fourth sub gate portion 161S4 in the first horizontal direction (the X direction).

As shown in FIG. 8, a source/drain region 131B of the integrated circuit device 101B may include a first protrusion 131_P1B, which overlaps the first sub gate portion 161S1B in the first horizontal direction (the X direction), and a second protrusion 131_P2B, which overlaps the second sub gate portion 161S2B in the first horizontal direction (the X direction).

In some example embodiments, the width of the source/drain region 131B in the first horizontal direction (the X direction) may be maximum at the second protrusion 131_P2B thereof. For example, the width of the source/drain region 131B in the first horizontal direction (the X direction), which is measured at a vertical level passing through the second protrusion 131_P2B, may be maximum. For example, the width of the source/drain region 131B in the first horizontal direction (the X direction), which is measured at a vertical level passing through the second sub gate portion 161S2B, may be maximum.

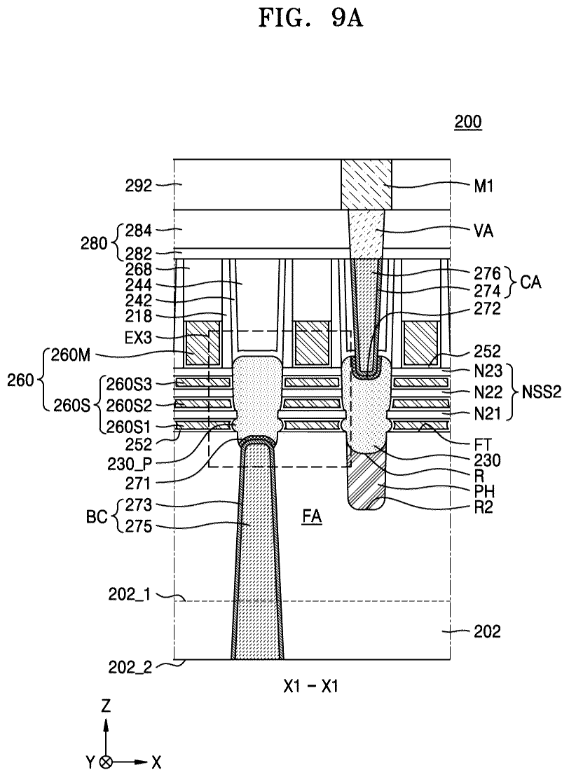

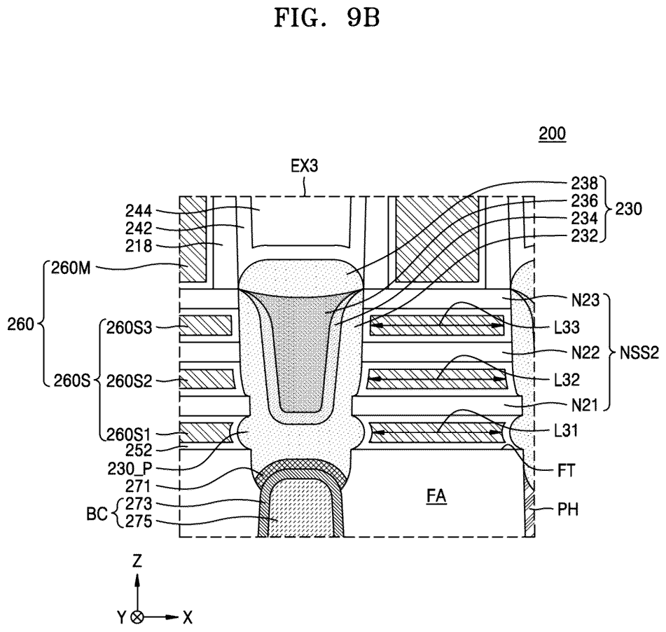

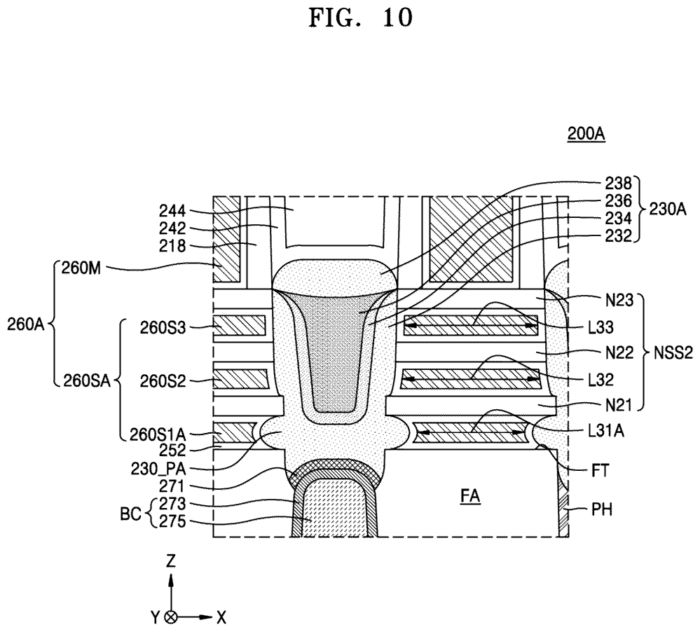

FIGS. 9A and 9B are cross-sectional views illustrating an integrated circuit device 200 according to some example embodiments. For example, FIG. 9B is an enlarged cross-sectional view of a region EX3 in FIG. 9A. FIGS. 10, 11, and 12 are enlarged cross-sectional views of regions, which correspond to the region EX3 in FIG. 9A in integrated circuit devices 200A, 201, and 201A, respectively, according to some example embodiments.

The integrated circuit device 200 is described below with reference to FIGS. 9A and 9B, focusing on the differences from the integrated circuit device 100 described above with reference to FIGS. 1 to 3.

Referring to FIGS. 9A and 9B, the integrated circuit device 200 may be provided. The integrated circuit device 200 may include a gate line 260, which extends long above a plurality of fin-type active regions FA in the second horizontal direction (the Y direction). Each of a plurality of nanosheet stacks NSS2 may be above the fin top FT of a fin-type active region FA where the fin-type active region FA intersects with one of the gate lines 260.

As shown in FIGS. 9A and 9B, each of the nanosheet stacks NSS2 may include a first nanosheet N21, a second nanosheet N22, and a third nanosheet N23, which overlap each other above the fin-type active region FA in the vertical direction (the Z direction).

In some example embodiments, the width of the first nanosheet N21 in the first horizontal direction (the X direction) may be greater than the width of the second nanosheet N22 in the first horizontal direction (the X direction). The width of the second nanosheet N22 in the first horizontal direction (the X direction) may be greater than the width of the third nanosheet N23 in the first horizontal direction (the X direction).

As shown in FIGS. 9A and 9B, each of the gate lines 260 may include a main gate portion 260M and a plurality of sub gate portions 260S.

Unlike the gate line 160 of the integrated circuit device 100, which may include four sub gate portions (e.g., 160S1 to 160S4) as described above with reference to FIGS. 1 to 3, each of the gate lines 260 of the integrated circuit device 200 may include three sub gate portions (e.g., 260S1 to 260S3). For example, the sub gate portions 260S may include a first sub gate portion 260S1 between the first nanosheet N21 and the fin-type active region FA, a second sub gate portion 260S2 between the first nanosheet N21 and the second nanosheet N22, and a third sub gate portion 260S3 between the second nanosheet N22 and the third nanosheet N23.

In some example embodiments, comparing the widths of the third sub gate portion 260S3 and the second sub gate portion 260S2 in the first horizontal direction (the X direction), a width L33 in the first horizontal direction (the X direction) of the third sub gate portion 260S3, which is located at a higher vertical level than the second sub gate portion 260S2, may be less than a width L32 of the second sub gate portion 260S2 in the first horizontal direction (the X direction).

In some example embodiments, a width L31 of the first sub gate portion 260S1 in the first horizontal direction (the X direction) may be less than the width L32 of the second sub gate portion 260S2 in the first horizontal direction (the X direction).

In some example embodiments, the width L31 of the first sub gate portion 260S1 in the first horizontal direction (the X direction) may be greater than or equal to the width L33 of the third sub gate portion 260S3 in the first horizontal direction (the X direction).

As shown in FIGS. 9A and 9B, the integrated circuit device 200 may include a plurality of source/drain regions 230. Each of the source/drain regions 230 may include a plurality of semiconductor layers. The semiconductor layers may include a first semiconductor layer 232, a second semiconductor layer 234, and a third semiconductor layer 236 that are sequentially arranged in each source/drain region 230. In some example embodiments, the semiconductor layers may further include a capping layer 238 on the third semiconductor layer 236.

In some example embodiments, each of the source/drain regions 230 may include a protrusion 230_P, which overlaps the first sub gate portion 260S1 in the first horizontal direction (the X direction).

In some example embodiments, the width of each of the source/drain regions 230 in the first horizontal direction (the X direction) may be minimum in a portion thereof that overlaps the first nanosheet N21. For example, the width of each source/drain region 230 in the first horizontal direction (the X direction), which is measured at a vertical level passing through the first nanosheet N21, may be minimum.

Referring to FIG. 10, the integrated circuit device 200A may be provided. The integrated circuit device 200A is described below, focusing on the differences from the integrated circuit device 200 described above with reference to FIGS. 9A and 9B.

The integrated circuit device 200A may include a gate line 260A, which extends long above a plurality of fin-type active regions FA in the second horizontal direction (the Y direction). The gate line 260A may include the main gate portion 260M and a plurality of sub gate portions 260SA. In some example embodiments, the sub gate portions 260SA may include a first sub gate portion 260S1A between the first nanosheet N21 and a fin-type active region FA, the second sub gate portion 260S2 between the first nanosheet N21 and the second nanosheet N22, and the third sub gate portion 260S3 between the second nanosheet N22 and the third nanosheet N23.

In some example embodiments, comparing the widths of the third sub gate portion 260S3 and the second sub gate portion 260S2 in the first horizontal direction (the X direction), the width L33 in the first horizontal direction (the X direction) of the third sub gate portion 260S3, which is located at a higher vertical level than the second sub gate portion 260S2, may be less than the width L32 of the second sub gate portion 260S2 in the first horizontal direction (the X direction).

In some example embodiments, a width L31A of the first sub gate portion 260S1A in the first horizontal direction (the X direction) may be less than the width L33 of the third sub gate portion 260S3 in the first horizontal direction (the X direction).

As shown in FIG. 10, the integrated circuit device 200A may include a source/drain region 230A. The source/drain region 230A may include a protrusion 230_PA, which overlaps the first sub gate portion 260S1A in the first horizontal direction (the X direction).

In some example embodiments, the width of the source/drain region 230A in the first horizontal direction (the X direction) may be maximum at the protrusion 230_PA thereof. For example, the width of the source/drain region 230A in the first horizontal direction (the X direction), which is measured at a vertical level passing through the protrusion 230_PA, may be maximum. For example, the width of the source/drain region 230A in the first horizontal direction (the X direction), which is measured at a vertical level passing through the first sub gate portion 260S1A, may be maximum.

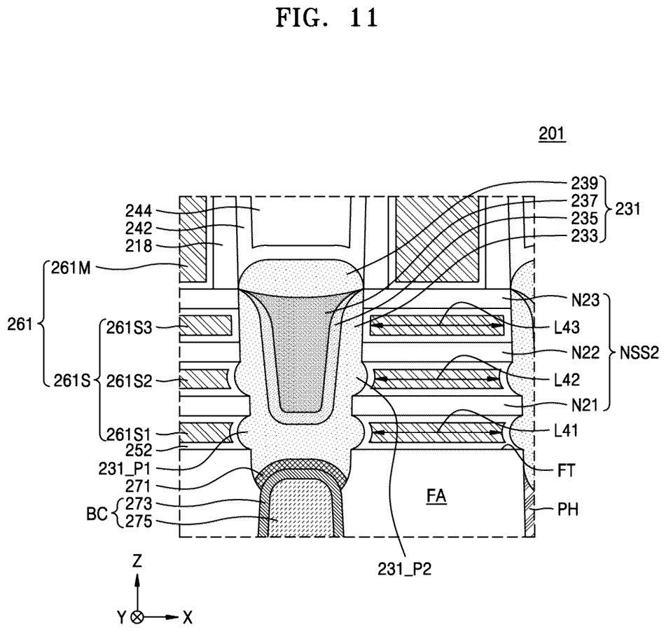

Referring to FIG. 11, the integrated circuit device 201 may be provided. The integrated circuit device 201 is described below, focusing on the differences from the integrated circuit device 200 described above with reference to FIGS. 9A and 9B.

The integrated circuit device 201 may include a gate line 261, which extends long above a plurality of fin-type active regions FA in the second horizontal direction (the Y direction). The gate line 261 may include a main gate portion 261M and a plurality of sub gate portions 261S. In some example embodiments, the sub gate portions 261S may include a first sub gate portion 261S1 between the first nanosheet N21 and a fin-type active region FA, a second sub gate portion 261S2 between the first nanosheet N21 and the second nanosheet N22, and a third sub gate portion 261S3 between the second nanosheet N22 and the third nanosheet N23.

In some example embodiments, comparing the widths of the second sub gate portion 261S2 and the first sub gate portion 261S1 in the first horizontal direction (the X direction), a width L42 in the first horizontal direction (the X direction) of the second sub gate portion 261S2, which is located at a higher vertical level than the first sub gate portion 261S1, may be less than a width L41 of the first sub gate portion 261S1 in the first horizontal direction (the X direction).

In some example embodiments, the width L42 of the second sub gate portion 261S2 in the first horizontal direction (the X direction) may be less than a width L43 of the third sub gate portion 261S3 in the first horizontal direction (the X direction).

In some example embodiments, the width L41 of the first sub gate portion 261S1 in the first horizontal direction (the X direction) may be greater than or equal to the width L43 of the third sub gate portion 261S3 in the first horizontal direction (the X direction).

As shown in FIG. 11, the integrated circuit device 201 may include a source/drain region 231. The source/drain region 231 may include a first protrusion 231_P1, which overlaps the first sub gate portion 261S1 in the first horizontal direction (the X direction), and a second protrusion 231_P2, which overlaps the second sub gate portion 261S2 in the first horizontal direction (the X direction).

In some example embodiments, the width of the source/drain region 231 in the first horizontal direction (the X direction) may be maximum at the second protrusion 231_P2 thereof. For example, the width of the source/drain region 231 in the first horizontal direction (the X direction), which is measured at a vertical level passing through the second protrusion 231_P2, may be maximum. For example, the width of the source/drain region 231 in the first horizontal direction (the X direction), which is measured at a vertical level passing through the second sub gate portion 261S2, may be maximum.

In some example embodiments, the width of the source/drain region 231 in the first horizontal direction (the X direction) may be minimum in a portion thereof that overlaps the first nanosheet N21. For example, the width of the source/drain region 231 in the first horizontal direction (the X direction), which is measured at a vertical level passing through the first nanosheet N21, may be minimum.

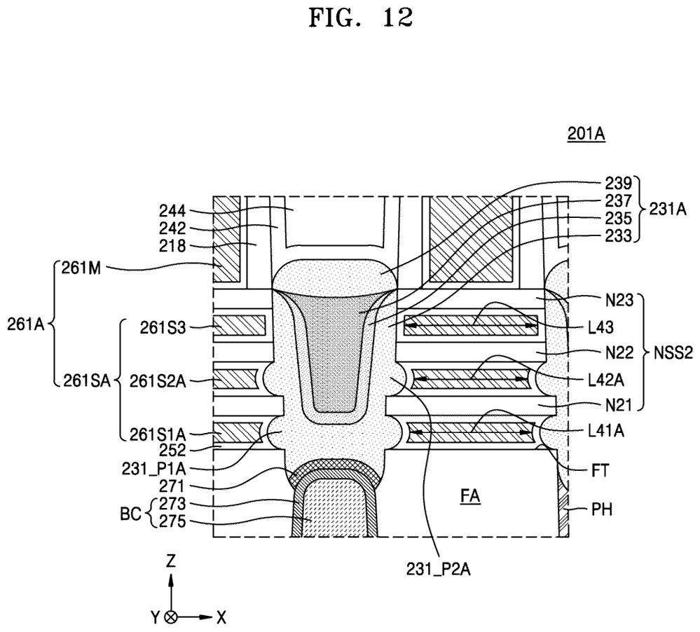

Referring to FIG. 12, the integrated circuit device 201A may be provided. The integrated circuit device 201A is described below, focusing on the differences from the integrated circuit device 201 described above with reference to FIG. 11.

The integrated circuit device 201A may include a gate line 261A, which extends long above a plurality of fin-type active regions FA in the second horizontal direction (the Y direction). The gate line 261A may include the main gate portion 261M and a plurality of sub gate portions 261SA. In some example embodiments, the sub gate portions 261SA may include a first sub gate portion 261S1A between the first nanosheet N21 and a fin-type active region FA, a second sub gate portion 261S2A between the first nanosheet N21 and the second nanosheet N22, and the third sub gate portion 261S3 between the second nanosheet N22 and the third nanosheet N23.

In some example embodiments, comparing the widths of the second sub gate portion 261S2A and the first sub gate portion 261S1A in the first horizontal direction (the X direction), a width L42A in the first horizontal direction (the X direction) of the second sub gate portion 261S2A, which is located at a higher vertical level than the first sub gate portion 261S1A, may be less than a width L41A of the first sub gate portion 261S1A in the first horizontal direction (the X direction).

In some example embodiments, each of the width L42A of the second sub gate portion 261S2A and the width L41A of the first sub gate portion 261S1A in the first horizontal direction (the X direction) may be less than the width L43 of the third sub gate portion 261S3 in the first horizontal direction (the X direction).

As shown in FIG. 12, the integrated circuit device 201A may include a source/drain region 231A. The source/drain region 231A may include a first protrusion 231_P1A, which overlaps the first sub gate portion 261S1A in the first horizontal direction (the X direction), and a second protrusion 231_P2A, which overlaps the second sub gate portion 261S2A in the first horizontal direction (the X direction).

In some example embodiments, the width of the source/drain region 231A in the first horizontal direction (the X direction) may be maximum at the second protrusion 231_P2A thereof. For example, the width of the source/drain region 231A in the first horizontal direction (the X direction), which is measured at a vertical level passing through the second protrusion 231_P2A, may be maximum. For example, the width of the source/drain region 231 in the first horizontal direction (the X direction), which is measured at a vertical level passing through the second sub gate portion 261S2A, may be maximum.

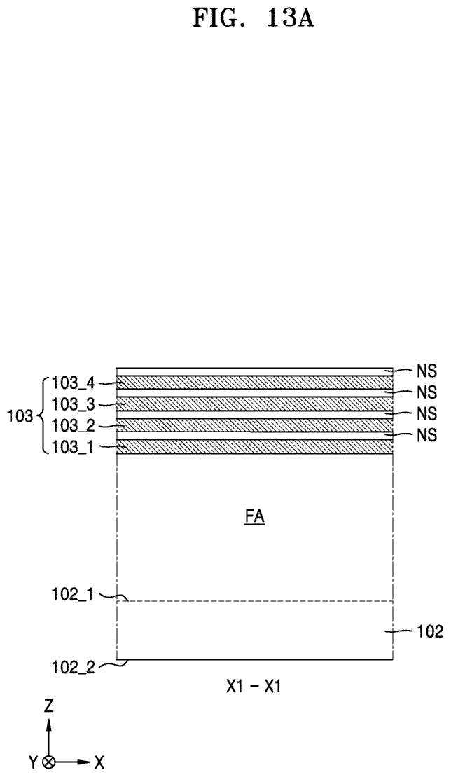

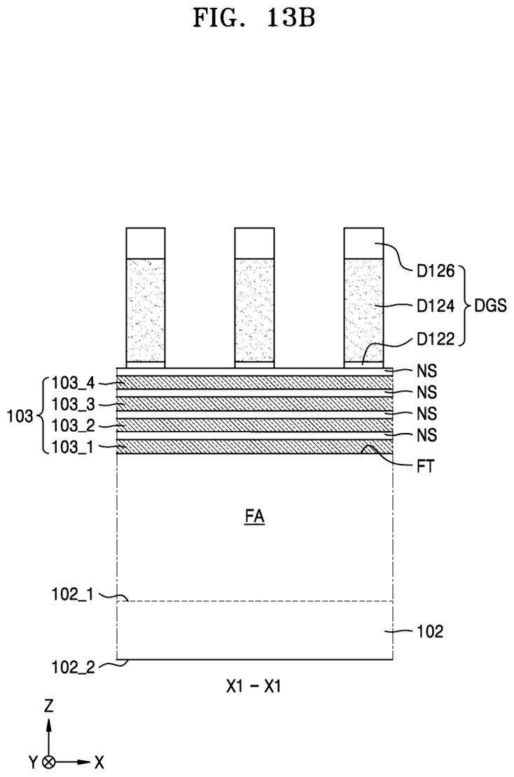

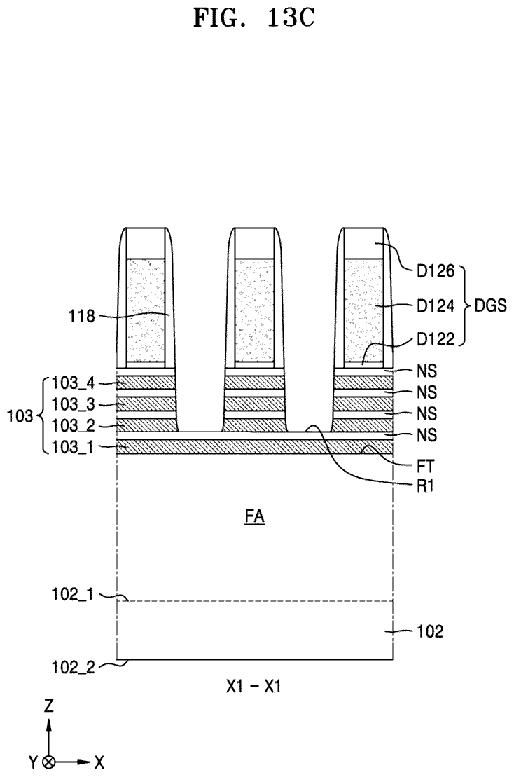

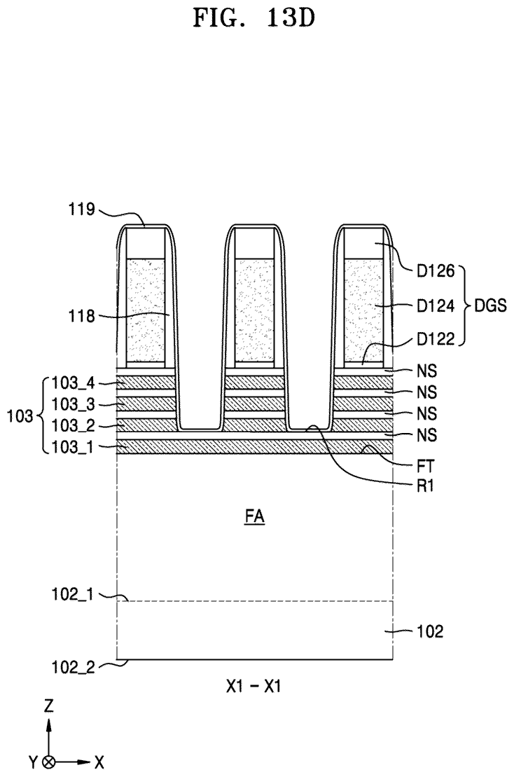

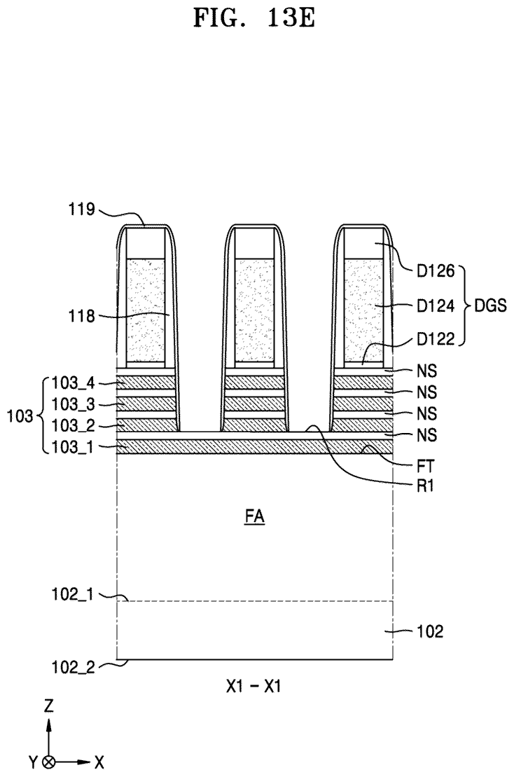

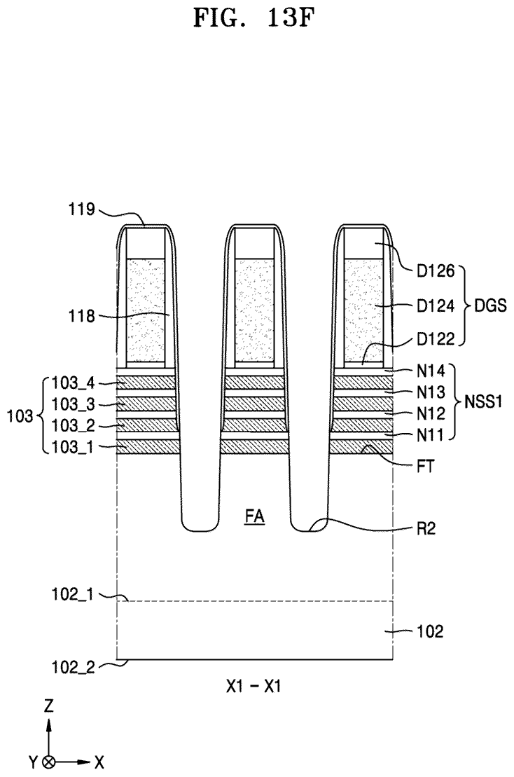

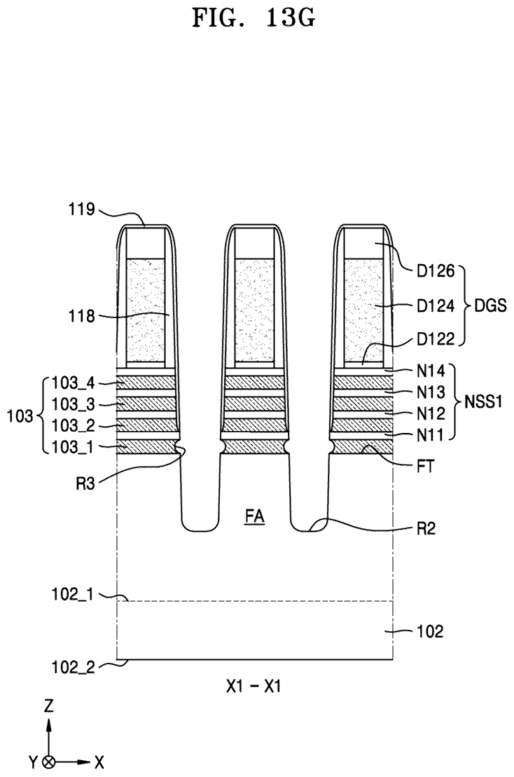

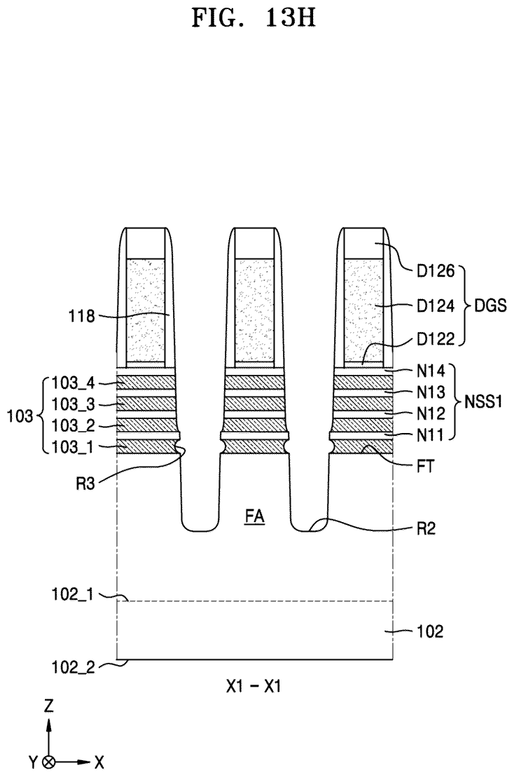

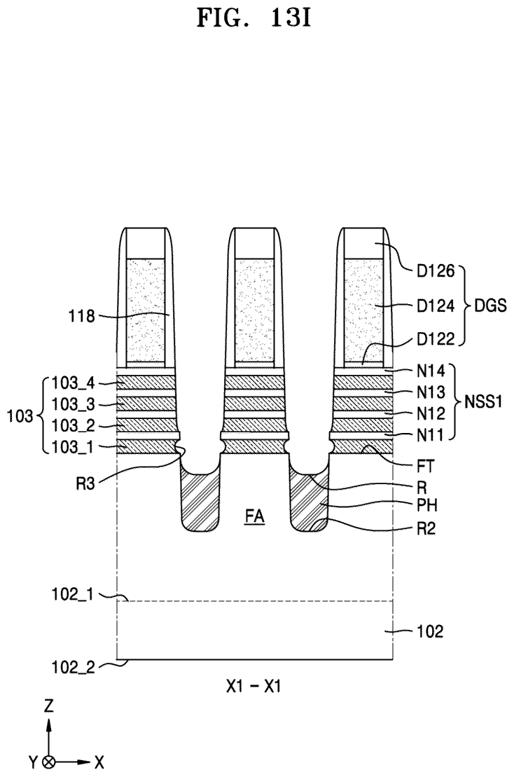

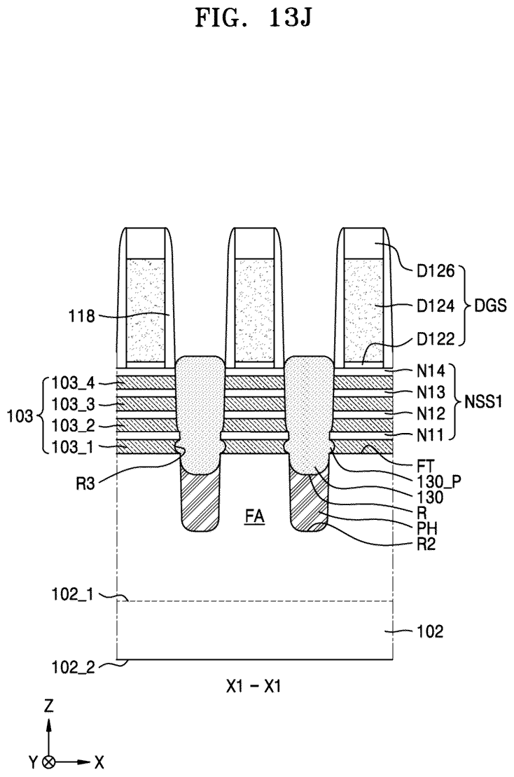

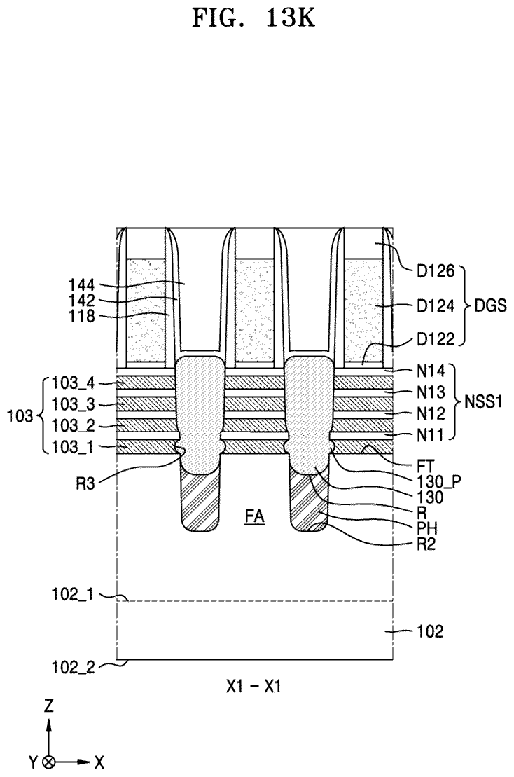

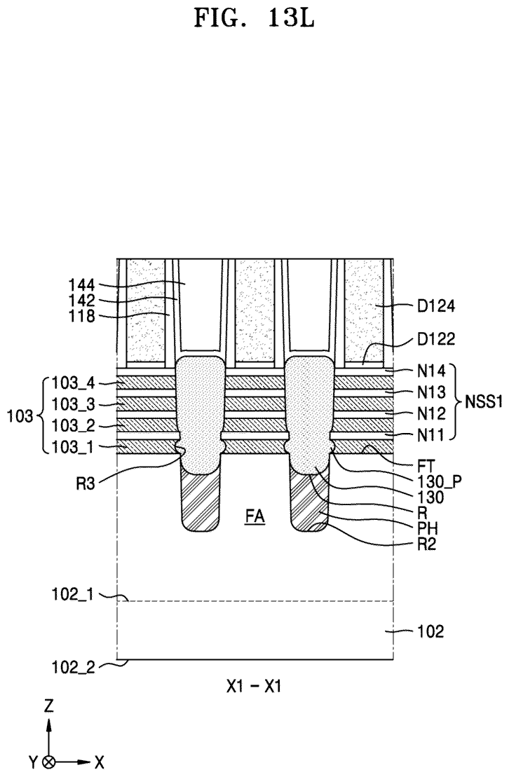

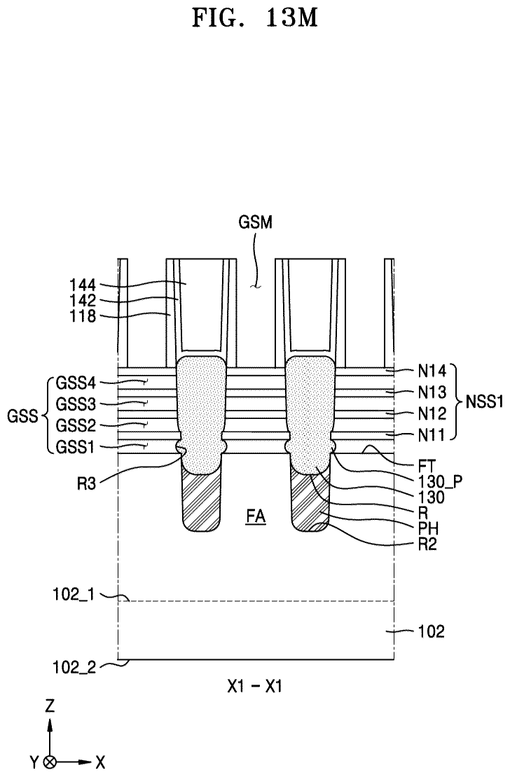

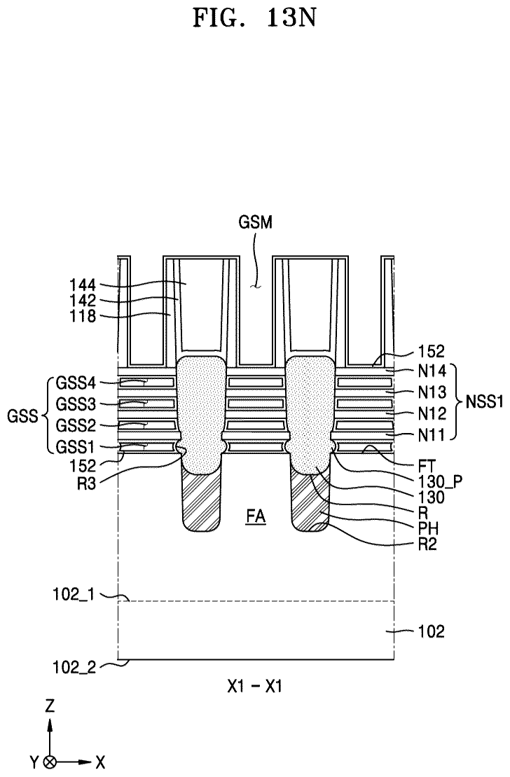

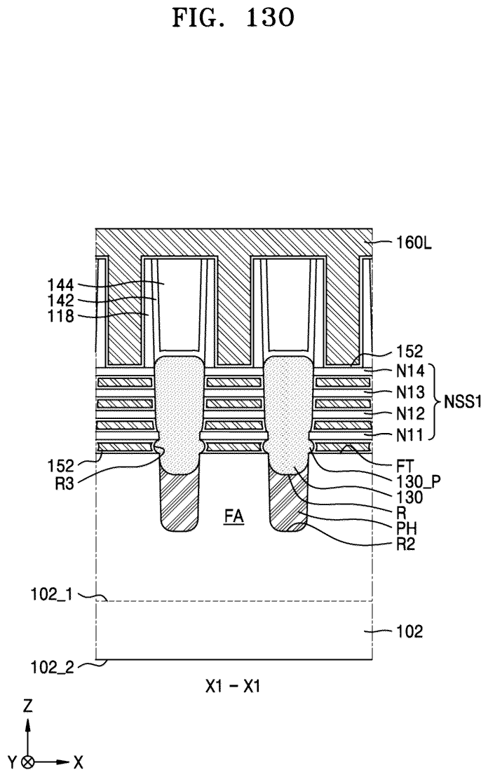

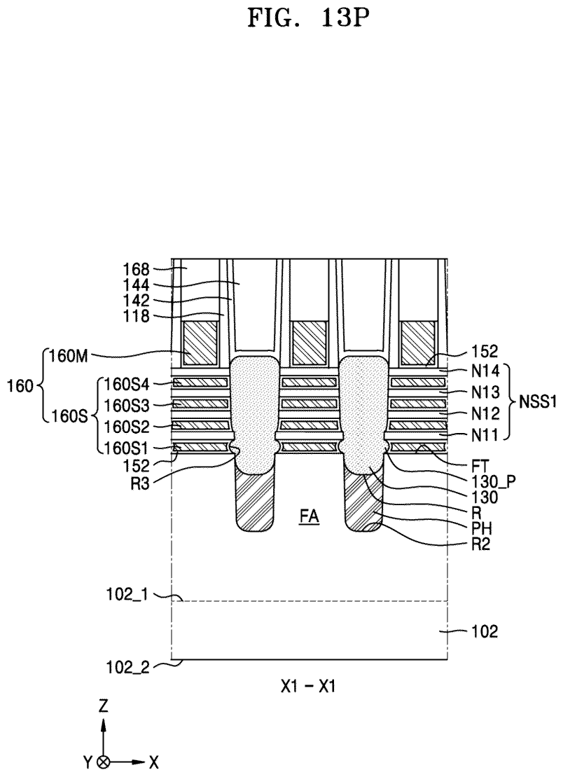

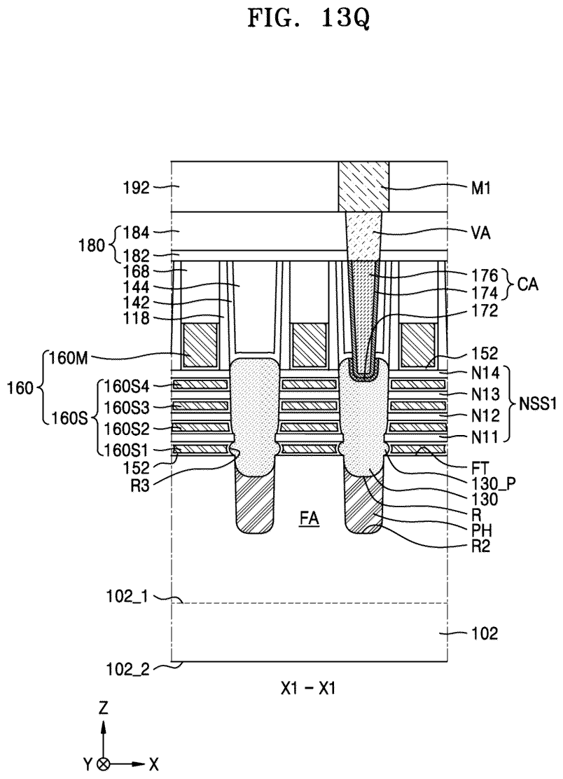

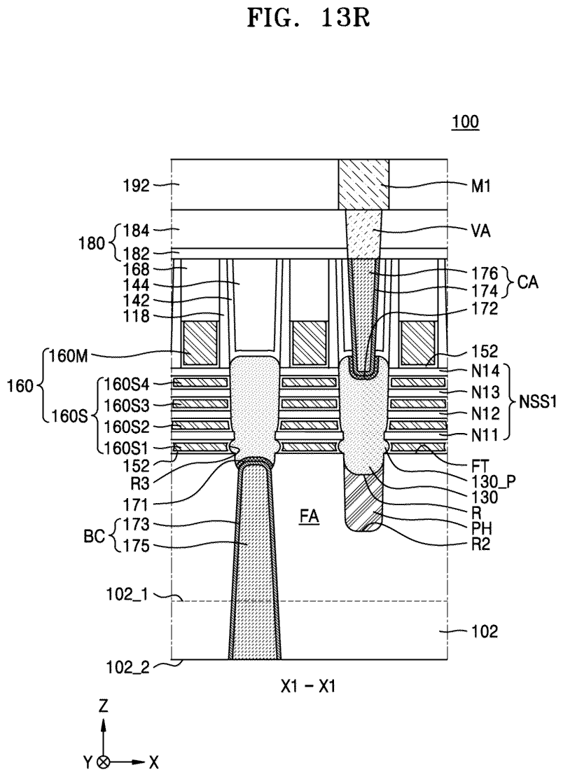

FIGS. 13A to 13R are cross-sectional views of sequential stages in a method of manufacturing the integrated circuit device 100, according to some example embodiments.

Referring to FIG. 13A, a plurality of sacrificial semiconductor layers 103 and a plurality of nanosheet semiconductor layers NS may be alternately stacked on the substrate 102. The sacrificial semiconductor layers 103 may include a first sacrificial semiconductor layer 103_1, a second sacrificial semiconductor layer 103_2, a third sacrificial semiconductor layer 103_3, and a fourth sacrificial semiconductor layer 103_4, which are sequentially stacked on the substrate 102. The sacrificial semiconductor layers 103 may include a semiconductor material having a different etch selectivity than a semiconductor material of the nanosheet semiconductor layers NS.

Thereafter, a plurality of fin-type active regions FA, which extend in the first horizontal direction (the X direction), may be formed by partially etching each of the sacrificial semiconductor layers 103, the nanosheet semiconductor layers NS, and the substrate 102. As a result, the first surface 102_1 of the substrate 102 may be formed and the fin-type active regions FA may be arranged on the first surface 102_1 of the substrate 102. A stack structure of the sacrificial semiconductor layers 103 and the nanosheet semiconductor layers NS may remain on the fin top FT of each of the fin-type active regions FA.

Referring to FIG. 13B, a plurality of dummy gate structures DGS may be formed on the stack structure of the sacrificial semiconductor layers 103 and the nanosheet semiconductor layers NS.

The dummy gate structures DGS may extend long in the second horizontal direction (the Y direction). Each of the dummy gate structures DGS may have a structure, in which an oxide film D122, a dummy gate layer D124, and a capping layer D126 are sequentially stacked. In some example embodiments, the dummy gate layer D124 may include polysilicon and the capping layer D126 may include a silicon nitride film.

Referring to FIG. 13C, outer insulating spacers 118 respectively covering opposite sidewalls of each of the dummy gate structures DGS may be formed. Thereafter, some of the sacrificial semiconductor layers 103 and some of the nanosheet semiconductor layers NS may be partially etched by using the dummy gate structure DGS and the outer insulating spacers 118 as etch masks. For example, the fourth sacrificial semiconductor layer 103_4, the third sacrificial semiconductor layer 103_3, and the second sacrificial semiconductor layer 103_2 among the sacrificial semiconductor layers 103 may be sequentially etched. Three nanosheet semiconductor layers NS at higher vertical levels among the plurality of nanosheet semiconductor layers NS may be partially etched.

A plurality of first recesses R1 may be formed by the etching process described above. The fourth sacrificial semiconductor layer 103_4, the third sacrificial semiconductor layer 103_3, and the second sacrificial semiconductor layer 103_2 may be exposed by the sidewalls of the first recesses R1. The bottom surface of the first recesses R1 may be at a higher vertical level than the first sacrificial semiconductor layer 103_1. The first sacrificial semiconductor layer 103_1 may not etched by the etching process described above. The first sacrificial semiconductor layer 103_1 may not be exposed by the first recesses R1. A nanosheet semiconductor layer NS between the first sacrificial semiconductor layer 103_1 and the second sacrificial semiconductor layer 103_2 may not be etched by the etching process described above. To form the first recesses R1, dry etching, wet etching, or a combination thereof may be used.

For example, the width of the first recesses R1 in the first horizontal direction (the X direction) may decrease downwards in the vertical direction (the Z direction). Accordingly, the widths in the first horizontal direction (the X direction) of the fourth sacrificial semiconductor layer 103_4, the third sacrificial semiconductor layer 103_3, and the second sacrificial semiconductor layer 103_2, which have been etched by the etching process, may increase downwards in the vertical direction (the Z direction). Similarly, the width in the first horizontal direction (the X direction) of the nanosheet semiconductor layers NS, which have been etched by the etching process, may increase downwards in the vertical direction (the Z direction).

Referring to FIG. 13D, a cover spacer 119 may be formed on the resultant structure of FIG. 13C. For example, the cover spacer 119 may be formed on the top surfaces of the dummy gate structures DGS, the side surfaces of the outer insulating spacers 118, and the sidewalls and bottom surfaces of the first recesses R1. As the cover spacer 119 is formed on the sidewalls and bottom surfaces of the first recesses R1, the fourth sacrificial semiconductor layer 103_4, the third sacrificial semiconductor layer 103_3, and the second sacrificial semiconductor layer 103_2 may not be exposed. For example, the cover spacer 119 may include at least one selected from the group consisting of SiN, SiO, and SiON.

Referring to FIG. 13E, the cover spacer 119 may be partially etched to expose the bottom surfaces of the first recesses R1.

Referring to FIG. 13F, the nanosheet semiconductor layer NS, which is between the first sacrificial semiconductor layer 103_1 and the second sacrificial semiconductor layer 103_2 and exposed by the bottom surfaces of the first recesses R1, the first sacrificial semiconductor layer 103_1, and the fin-type active region FA may be partially etched by using the cover spacer 119 as an etch mask.

Through the etching process described above, the nanosheet semiconductor layers NS may be made into a plurality of nanosheet stacks NSS1 and a plurality of second recesses R2 may be formed in an upper portion of the fin-type active region FA. Each of the nanosheet stacks NSS1 may include a first nanosheet N11, a second nanosheet N12, a third nanosheet N13, and a fourth nanosheet N14. The first sacrificial semiconductor layer 103_1 may be exposed by the sidewalls of the second recesses R2. To form the second recesses R2, dry etching, wet etching, or a combination thereof may be used.

Referring to FIG. 13G, the first sacrificial semiconductor layer 103_1 exposed by the sidewalls of the second recesses R2 may be etched. For example, a plurality of third recesses R3 may be formed by etching the first sacrificial semiconductor layer 103_1 in the first horizontal direction (the X direction).

Referring to FIGS. 13H and 13I, the cover spacer 119 may be removed, and place holders PH may be formed to respectively fill the second recesses R2. Through the process described above, recesses R may be respectively formed above the second recesses R2.

Referring to FIG. 13J, a plurality of source/drain regions 130 may be respectively formed in the recesses R. In some example embodiments, the source/drain regions 130 may be formed by epitaxially growing a semiconductor material from a surface of the fin-type active region FA exposed at the bottoms of the recesses R, the sidewalls of the first nanosheet N11, the second nanosheet N12, the third nanosheet N13, and the fourth nanosheet N14, which are included in each of the nanosheet stacks NSS1, and the sidewalls of the sacrificial semiconductor layers 103. A protrusion 130_P may also be formed in each of the third recesses R3.

Referring to FIG. 13K, an insulating liner 142 may be formed to cover the resultant structure of FIG. 13J, which includes the source/drain regions 130, and an intergate insulating film 144 may be formed on the insulating liner 142. Thereafter, the top surface of the capping layer D126 may be exposed by planarizing the insulating liner 142 and the intergate insulating film 144.

Referring to FIG. 13L, the top surface of the dummy gate layer D124 may be exposed by removing the capping layer D126. The insulating liner 142 and the intergate insulating film 144 may be partially removed such that the top surface of the intergate insulating film 144 may be substantially coplanar with the top surface of the dummy gate layer D124.

Referring to FIG. 13M, a main gate space GSM may be formed by removing the dummy gate layer D124 and the oxide film D122 below the dummy gate layer D124 such that each of the nanosheet stacks NSS1 may be exposed by the main gate space GSM.

Thereafter, a sub gate space GSS may be formed among the first nanosheet N11, the second nanosheet N12, the third nanosheet N13, the fourth nanosheet N14, and the fin top FT of the fin-type active region FA by removing the sacrificial semiconductor layers 103, which remain on the fin-type active region FA, through the main gate space GSM. For example, a first sub gate space GSS1 may be formed between the first nanosheet N11 and the fin top FT of the fin-type active region FA, a second sub gate space GSS2 may be formed between the first nanosheet N11 and the second nanosheet N12, a third sub gate space GSS3 may be formed between the second nanosheet N12 and the third nanosheet N13, and a fourth sub gate space GSS4 may be formed between the third nanosheet N13 and the fourth nanosheet N14.

In some example embodiments, to selectively remove the sacrificial semiconductor layers 103, a difference in etch selectivity between the sacrificial semiconductor layers 103 and the first nanosheet N11, the second nanosheet N12, the third nanosheet N13, and the fourth nanosheet N14 may be provided.

Referring to FIG. 13N, a gate dielectric film 152 may be formed in the main gate space GSM and the sub gate space GSS. The gate dielectric film 152 may be formed to cover the exposed surface of the fourth nanosheet N14 in the main gate space GSM. The gate dielectric film 152 may be formed to cover the first nanosheet N11, the second nanosheet N12, the third nanosheet N13, and the fourth nanosheet N14 in the sub gate space GSS. The gate dielectric film 152 may be formed using atomic layer deposition (ALD).

Referring to FIG. 130, a gate forming conductive layer 160L may be formed on the gate dielectric film 152 to fill the main gate space GSM and the sub gate space GSS and cover the top surface of the intergate insulating film 144. The gate forming conductive layer 160L may include metal, metal nitride, metal carbide, or a combination thereof. The gate forming conductive layer 160L may be formed using ALD or CVD.

Referring to FIG. 13P, an upper portion of the gate forming conductive layer 160L may be removed to expose the top surface of the intergate insulating film 144 and empty an upper portion of the main gate space GSM (see FIG. 13N). As a result, a plurality of gate lines 160 may be formed from the gate forming conductive layer 160L.

For example, due to the protrusion 130_P filling each of the third recesses R3, the width of the first sub gate portion 160S1, which overlaps the protrusion 130_P in the first horizontal direction (the X direction), may be less than the width of at least one of the sub gate portions 160S, which does not overlap the protrusion 130_P in the first horizontal direction (the X direction), in the first horizontal direction (the X direction).

An upper portion of each of the gate dielectric film 152 and the outer insulating spacers 118 may be consumed in the main gate space GSM so that the height of each of the gate dielectric film 152 and the outer insulating spacers 118 may decrease. Thereafter, a capping insulating pattern 168 may be formed on each of the gate lines 160 to fill the main gate space GSM.

Referring to FIG. 13Q, a source/drain contact hole penetrating an insulating structure including the insulating liner 142 and the intergate insulating film 144 may be formed to expose one of the source/drain regions 130. Thereafter, the source/drain contact hole may be made to extend further toward the substrate 102 by anisotropically etching the source/drain region 130 through the source/drain contact hole. Thereafter, a first metal silicide film 172 may be formed on the exposed surface of the source/drain region 130 at the bottom of the source/drain contact hole. In some example embodiments, the forming of the first metal silicide film 172 may include forming a metal liner (not shown) to conformally cover the exposed surface of the source/drain region 130 and inducing a reaction between the source/drain region 130 and metal included in the metal liner by performing a heat treatment on the metal liner. After the first metal silicide film 172 is formed, the residue of the metal liner may be removed. During the process of forming the first metal silicide film 172, the source/drain region 130 may be partially consumed. In some example embodiments, when the first metal silicide film 172 includes a titanium silicide film, the metal liner may include a Ti film.

Thereafter, a source/drain contact CA including a conductive barrier pattern 174 and a contact plug 176 may be formed on the first metal silicide film 172.

Subsequently, an upper insulating structure 180 may be formed on the intergate insulating film 144 and the source/drain contact CA, and a via contact VA may be formed through the upper insulating structure 180 to be connected to the source/drain contact CA. Subsequently, an upper insulating film 192 may be formed on the upper insulating structure 180 and the via contact VA, and an interconnection line M1 penetrating the upper insulating film 192 may be formed.

Referring to FIG. 13R, a backside contact BC may be formed through the substrate 102 and the fin-type active region FA to be connected to a source/drain region 130. The process of forming the backside contact BC may include using a place holder PH as a marker. Through the processes described above, the integrated circuit device 100 described with reference to FIGS. 1 to 3 may be manufactured.

Although a method of manufacturing the integrated circuit device 100 described with reference to FIGS. 1 to 3 has been described above with reference to FIGS. 13A to 13R, those skilled in the art will be well aware that the integrated circuit devices 100A, 100B, 101, 101A, 101B, 200, 200A, 202, and 201A illustrated in FIGS. 4 to 12 and other integrated circuit devices having various structures changed and modified from the integrated circuit devices 100A, 100B, 101, 101A, 101B, 200, 200A, 201, and 201A may be manufactured by making various changes and modifications in the descriptions of FIGS. 13A to 13R within the scope of the technical spirit of the inventive concepts.

For example, in some example embodiments, before the backside contact BC is formed, a semiconductor material may be completely removed from the fin-type active region FA and the substrate 102, and replaced with an insulating material. In some example embodiments, the fin-type active region FA may correspond to a fin-type pattern including the insulating material and the substrate 102 may correspond to an insulating substrate including the insulating material in some example embodiments described above. In some example embodiments, the insulating material may include the same material as the isolation film 112. In some example embodiments, the insulating material may include a different material than the isolation film 112. The insulating material may include at least one selected from the group consisting of silicon oxide (SiO₂), silicon nitride (SiN), silicon carbonitride (SiCN), silicon oxynitride (SiON), silicon oxycarbide (SiOC), and silicon oxycarbonitride (SiOCN).

While the inventive concepts have been shown and described with reference to some example embodiments thereof, it will be understood that various changes in form and detail may be made therein without departing from the spirit and scope of the following claims.

1. An integrated circuit device comprising:
a fin-type active region extending in a first horizontal direction on a substrate;
a nanosheet stack including a plurality of nanosheets facing a fin top of the fin-type active region, the nanosheet stack is separated from the fin top of the fin-type active region;
a gate line on the fin-type active region, the gate line surrounding each of the plurality of nanosheets and the gate line extending in a second horizontal direction that crosses the first horizontal direction;
a source/drain region on the fin-type active region, the source/drain region being adjacent to the gate line and the source/drain region being in contact with the plurality of nanosheets; and
a backside contact penetrating the substrate and the backside contact electrically connected to the source/drain region,
wherein the gate line includes a main gate portion on a top surface of the nanosheet stack and a plurality of sub gate portions between the main gate portion and the fin-type active region,
the plurality of sub gate portions include a first sub gate portion on the fin top of the fin-type active region, a second sub gate portion on the first sub gate portion, and a third sub gate portion on the second sub gate portion, and
a width of the first sub gate portion in the first horizontal direction is greater than or equal to a width of the third sub gate portion in the first horizontal direction and the width of the first sub gate portion is less than a width of the second sub gate portion in the first horizontal direction.

2. The integrated circuit device of claim 1, further comprising
a fourth sub gate portion between the second sub gate portion and the third sub gate portion,
wherein a width of the fourth sub gate portion in the first horizontal direction is greater than the width of the first sub gate portion in the first horizontal direction and the width of the fourth sub gate portion is less than the width of the second sub gate portion in the first horizontal direction.

3. The integrated circuit device of claim 1, further comprising
a fourth sub gate portion between the second sub gate portion and the third sub gate portion,
wherein a width of the fourth sub gate portion in the first horizontal direction is greater than the width of the third sub gate portion in the first horizontal direction and the width of the fourth sub gate portion is less than or equal to the width of the first sub gate portion in the first horizontal direction.

4. The integrated circuit device of claim 1, further comprising
a fourth sub gate portion between the first sub gate portion and the fin top of the fin-type active region,
wherein a width of the fourth sub gate portion in the first horizontal direction is greater than the width of the first sub gate portion in the first horizontal direction and the width of the fourth sub gate portion is less than or equal to the width of the second sub gate portion in the first horizontal direction.

5. The integrated circuit device of claim 1, further comprising
a fourth sub gate portion between the first sub gate portion and the fin top of the fin-type active region,
wherein a width of the fourth sub gate portion in the first horizontal direction is greater than or equal to the width of the second sub gate portion in the first horizontal direction.

6. The integrated circuit device of claim 1, wherein
the plurality of nanosheets include:
a first nanosheet between the first sub gate portion and the second sub gate portion;
a second nanosheet between the second sub gate portion and the third sub gate portion; and
a third nanosheet between the third sub gate portion and the main gate portion, and
a width of the first nanosheet in the first horizontal direction is greater than a width of the second nanosheet in the first horizontal direction.

7. An integrated circuit device comprising:
a fin-type active region extending in a first horizontal direction on a substrate;
a channel region on the fin-type active region;
a gate line on the fin-type active region, the gate line surrounding the channel region and the gate line extending in a second horizontal direction that crosses the first horizontal direction; and
a source/drain region on the fin-type active region, the source/drain region being adjacent to the gate line and the source/drain region being in contact with the channel region,
wherein the gate line includes a main gate portion and a plurality of sub gate portions between the main gate portion and the fin-type active region, the main gate portion being at a higher vertical level than the channel region,
the plurality of sub gate portions include a first sub gate portion on a fin top of the fin-type active region, a second sub gate portion on the first sub gate portion, and a third sub gate portion on the second sub gate portion,
a width of the first sub gate portion in the first horizontal direction is less than a width of the second sub gate portion in the first horizontal direction,
the first sub gate portion includes a first side surface and a second side surface overlapping the first side surface in the first horizontal direction, and
the first side surface of the first sub gate portion is indented toward the second side surface of the first sub gate portion.

8. The integrated circuit device of claim 7, wherein the first sub gate portion includes a portion having a width in the first horizontal direction that decreases and thereafter increases at increasing vertical levels of the first sub gate portion.

9. The integrated circuit device of claim 7, wherein the second side surface of the first sub gate portion is indented toward the first side surface of the first sub gate portion.

10. The integrated circuit device of claim 7, wherein
the source/drain region includes:
a first semiconductor layer including a portion in contact with the channel region and a portion in contact with the fin-type active region; and
a second semiconductor layer on the first semiconductor layer, and
the first semiconductor layer includes a protrusion overlapping the first sub gate portion in the first horizontal direction.

11. The integrated circuit device of claim 10, wherein the protrusion includes a portion overlapping the second sub gate portion in a vertical direction.

12. The integrated circuit device of claim 7, wherein the width of the first sub gate portion in the first horizontal direction is less than or equal to a width of the third sub gate portion in the first horizontal direction.

13. The integrated circuit device of claim 12, further comprising
a fourth sub gate portion between the second sub gate portion and the third sub gate portion,
wherein a width of the fourth sub gate portion in the first horizontal direction is greater than the width of the third sub gate portion in the first horizontal direction and the width of the fourth sub gate portion is less than the width of the second sub gate portion in the first horizontal direction.

14. The integrated circuit device of claim 12, further comprising
a fourth sub gate portion between the first sub gate portion and the fin top of the fin-type active region,
wherein a width of the fourth sub gate portion in the first horizontal direction is greater than the width of the third sub gate portion in the first horizontal direction and the width of the fourth sub gate portion is greater than the width of the first sub gate portion in the first horizontal direction.

15. The integrated circuit device of claim 12, further comprising
a fourth sub gate portion between the first sub gate portion and the fin top of the fin-type active region,
wherein a width of the fourth sub gate portion in the first horizontal direction is greater than the width of the first sub gate portion in the first horizontal direction and the width of the fourth sub gate portion is less than or equal to the width of the third sub gate portion in the first horizontal direction.

16. The integrated circuit device of claim 7, wherein the width of the first sub gate portion in the first horizontal direction is greater than or equal to a width of the third sub gate portion in the first horizontal direction.

17. The integrated circuit device of claim 7, further comprising a backside contact penetrating the substrate and electrically connected to the source/drain region.

18. An integrated circuit device comprising:
a fin-type active region extending in a first horizontal direction on a substrate;
a nanosheet stack including a plurality of nanosheets facing a fin top of the fin-type active region, the nanosheet stack is separated from the fin top of the fin-type active region;
a gate line on the fin-type active region, the gate line surrounding each of the plurality of nanosheets and the gate line extending in a second horizontal direction that crosses the first horizontal direction; and
a source/drain region on the fin-type active region, the source/drain region being adjacent to the gate line and the source/drain region being in contact with the plurality of nanosheets,
wherein the gate line includes a main gate portion on a top surface of the nanosheet stack and the gate line includes a plurality of sub gate portions respectively below the plurality of nanosheets,
the plurality of sub gate portions include a first sub gate portion, a second sub gate portion, a third sub gate portion, and a fourth sub gate portion that are sequentially arranged on the fin top of the fin-type active region,
a width of the second sub gate portion in the first horizontal direction is greater than a width of the first sub gate portion in the first horizontal direction and the width of the second sub gate portion is less than a width of the third sub gate portion in the first horizontal direction,
a width of the fourth sub gate portion in the first horizontal direction is less than the width of the third sub gate portion in the first horizontal direction,
the plurality of nanosheets include a first nanosheet between the first sub gate portion and the second sub gate portion, a second nanosheet between the second sub gate portion and the third sub gate portion, a third nanosheet between the third sub gate portion and the fourth sub gate portion, and a fourth nanosheet between the fourth sub gate portion and the main gate portion, and
a width of the fourth nanosheet in the first horizontal direction is greater than a width of the third nanosheet in the first horizontal direction.

19. The integrated circuit device of claim 18, wherein
the first sub gate portion includes a first side surface and a second side surface overlapping the first side surface in the first horizontal direction, and
the first side surface of the first sub gate portion is indented toward the second side surface of the first sub gate portion.

20. The integrated circuit device of claim 18, wherein
the source/drain region includes:
a first semiconductor layer including a portion in contact with the plurality of nanosheets and a portion in contact with the fin-type active region; and
a second semiconductor layer on the first semiconductor layer, and
the first semiconductor layer includes a protrusion overlapping the first sub gate portion in the first horizontal direction.
